(19) United States
(12) Patent Application Publication
(10) Pub. No.: US 2010/0154861 A1
(43) Pub. Date: Jun. 24, 2010

(54) PRINTED SOLAR PANEL

(75) Inventor: John K. Gritters, Livermore, CA (US)

Correspondence Address: N. KENNETH BURRASTON;KIRTON & MCCONKIE, P.O. BOX 45120, SALT LAKE CITY, UT, 84145-0120, US

(73) Assignee: FORMFACTOR, INC.

(21) Appl. No.: 12/343,135

(22) Filed: Dec. 23, 2008

(51) Int. Cl. H01L 31/052; H01L 31/042; H01L 31/18

(52) U.S. Cl. 136/246; 136/244; 438/63; 257/E21.211; 977/773

(57) ABSTRACT

A solar panel can include a substrate with layers of droplets of different materials disposed on a surface of the substrate. An outer layer can be disposed away from the surface and can comprise a face of the solar panel. The layers can comprise a cathode electrode and an anode electrode disposed between the outer layer and the surface of the substrate. The layers can further comprise a P region and an N region. The P region can be disposed at least partially around the anode electrode. The N region can be disposed at least partially around the P region and at least partially around the cathode electrode. The P region and the N region can comprise droplets of a P material comprising P-doped semiconductor particles and an N material comprising N-doped semiconductor particles respectively.

### BACKGROUND

Solar energy is a clean, renewable, environmentally friendly source of energy. Solar panels typically comprise one or more solar cells. A typical solar cell is made of doped silicon materials, which convert light (e.g., from the sun) into electrical energy. Such solar panels are increasingly being used to meet electrical power needs in a home, community, or city. Some embodiments of the present invention are directed to improved solar panels and improved processes of making solar panels.

### SUMMARY

In some embodiments of the invention, a solar panel can comprise a substrate and layers of droplets of different materials disposed on a surface of the substrate. The layers of materials can comprise an outer layer, which can be disposed away from the surface of the substrate and can comprise a face of the solar panel. The layers can also comprise a cathode electrode and an anode electrode both of which can be disposed between the outer layer and the surface of the substrate. The layers can further comprise a P region and an N region. The P region can be disposed at least partially around the anode electrode, and the P region can comprise droplets of a P material comprising P-doped semiconductor particles. The N region can be disposed at least partially around the P region and at least partially around the cathode electrode, and the N region can comprise droplets of an N material comprising N-doped semiconductor particles.

In some embodiments of the invention, a method of making a solar panel can comprise depositing a plurality of layers of droplets of different materials on a surface of a substrate and on a cathode electrode and an anode electrode located on the surface of the substrate. The layers of droplets of different materials can be deposited to form a P region at least partially around the anode electrode and an N region at least partially around the cathode electrode. The P region can be formed by depositing droplets of a P material comprising P-doped semiconductor particles onto the surface of the substrate and at least partially around the anode electrode. The N region can be formed by depositing droplets of an N material comprising N-doped semiconductor particles onto the surface and at least partially around the cathode electrode and the P region.

In some embodiments of the invention, a method of generating an electric current can comprise exposing a face of a solar panel to light. The face can comprise an outer layer of a plurality of layers of droplets of different materials disposed on a surface of a substrate. The layers can include a P region that can be disposed at least partially around an anode electrode located on the surface of the substrate, and the layers can include an N region that can be disposed at least partially around the P region and at least partially around a cathode electrode located on the surface of the substrate. The P region can comprise droplets of a material comprising P-doped semiconductor particles, and the N region can comprise droplets of a material comprising N-doped semiconductor particles. The light that strikes the face can enter the layers and strike a depletion region between the P region and the N region, which can generate a current flow from the cathode electrode to the anode electrode.

In some embodiments of the invention, a solar panel can comprise a substrate, which can include a cathode electrode disposed on a first base, which can have a triangular cross-section with converging sidewalls each disposed at an angle with respect to the surface of the substrate of 20 to 70 degrees. The substrate can also comprise an anode electrode disposed on a second base, which can have a triangular cross-section with converging sidewalls each disposed at an angle with respect to the surface of the substrate of 20 to 70 degrees. The solar panel can further comprise layers of droplets of materials disposed on the surface of the substrate, the cathode, and the anode. The layers of materials can comprise an outer layer, a P region, and an N region. The outer layer can be disposed away from the surface of the substrate and can include angled portions each angled with respect to the surface of the substrate at an angle that is approximately equal to one of the angles of one of the sidewalls of the first base or the second base. The P region can be disposed at least partially around the anode electrode, and the P region can comprise droplets of a P material comprising P-doped semiconductor particles. The N region can be disposed at least partially around the P region and at least partially around the cathode electrode, and the N region can comprise droplets of an N material comprising N-doped semiconductor particles.

### BRIEF DESCRIPTION OF THE DRAWINGS

FIG. 1 illustrates a partial, cross-sectional side view of a solar panel according to some embodiments of the invention.

FIG. 2 illustrates a partial, cross-sectional side view of another solar panel according to some embodiments of the invention.

FIG. 3 illustrates an equivalent circuit of a solar cell in which the solar cell is represented by a current source.

FIG. 4 illustrates an equivalent circuit in which a plurality of solar cells (each represented by a current source) are connected in parallel.

FIG. 5 illustrates an equivalent circuit in which a plurality of solar cells (each represented by a current source) are connected in series.

FIG. 6 illustrates a perspective view of a substrate with cathode electrodes and anode electrodes of solar cells to be made on the substrate are connected by traces in parallel as in FIG. 4 according to some embodiments of the invention.

FIG. 7 illustrates a perspective view of a substrate with cathode electrodes and anode electrodes of solar cells to be made on the substrate are connected by traces in series as in FIG. 5 according to some embodiments of the invention.

FIG. 8A illustrates a printing apparatus that can be used to print one or more elements of the solar panel of FIG. 2 on the substrate of FIG. 6 or FIG. 7 according to some embodiments of the invention.

FIG. 8B illustrates a print head of the printing apparatus of FIG. 4B according to some embodiments of the invention.

FIGS. 9A and 9B illustrate a top view and a cross-sectional side view, respectively, of the substrate of FIG. 6 or FIG. 7 after elements of the solar panel of FIG. 2 have be formed on the substrate according to some embodiments of the invention.

FIGS. 10A and 10B illustrate a top view and a cross-sectional side view, respectively, of the substrate of FIG. 6 or FIG. 7 after elements of the solar panel of FIG. 2 have be formed on the substrate according to some embodiments of the invention.

FIGS. 11A and 1B illustrate a top view and a cross-sectional side view, respectively, of the substrate of FIG. 6 or FIG. 7 after still more elements of the solar panel of FIG. 2 have be formed on the substrate according to some embodiments of the invention.

FIG. 12 illustrates an example of a solar panel in which solar cells include multiple stacked P regions according to some embodiments.

FIG. 13 illustrates another example of a solar panel in which solar cells include multiple stacked P regions according to some embodiments of the invention.

FIG. 14A illustrates an example of a solar panel in which a face of the solar panel includes angled portions according to some embodiments of the invention.

FIG. 14B illustrates an example of a base of the solar panel of FIG. 14A.

FIG. 15 illustrates an example of a solar panel in which a face of the solar panel includes angled portions and in which solar cells include multiple stacked P regions according to some embodiments of the invention.

FIG. 16 illustrates an equivalent circuit including a solar cell represented by a current source and a by-pass diode.

FIG. 17 illustrates an example of a solar panel in which the solar cell and the by-pass diode of FIG. 16 are formed in layers of different materials on the substrate according to some embodiments of the invention.

FIG. 18 illustrates an equivalent circuit including a solar cell represented by a current source and a clamping diode according to some embodiments of the invention.

FIG. 19 illustrates an example of a solar panel in which the solar cell and the clamping diode of FIG. 18 are formed in layers of different materials on the substrate according to some embodiments of the invention.

FIG. 20 illustrates an example of a Schottky solar cell according to some embodiments of the invention.

FIG. 21 illustrates another example of a Schottky solar cell according to some embodiments of the invention.

FIG. 22 illustrates an example in which additional layers of material are applied to a solar panel to enhance optical characteristics of the panel according to some embodiments of the invention.

FIGS. 23A-23D illustrate a system for making solar panels according to some embodiments of the invention.

### DETAILED DESCRIPTION OF EXEMPLARY EMBODIMENTS

This specification describes exemplary embodiments and applications of the invention. The invention, however, is not limited to these exemplary embodiments and applications or to the manner in which the exemplary embodiments and applications operate or are described herein. Moreover, the Figures may show simplified or partial views, and the dimensions of elements in the Figures may be exaggerated or otherwise not in proportion for clarity. In addition, as the terms “on” and “attached to” are used herein, one object (e.g., a material, a layer, a substrate, etc.) can be “on” or “attached to” another object regardless of whether the one object is directly on or attached to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

In some embodiments, a solar panel can be made by printing on a substrate the electrodes and doped semiconductor regions of the solar panel. For example, droplets of a solution containing particles of a conductive material can be printed on the substrate, forming the electrodes of the solar panel. Droplets of different solutions each containing a semiconductor material with a particular type and concentration of doping can also be printed on the substrate, forming different P-doped and N-doped semiconductor regions of the solar panel. Printing the solar panel can be an economical and efficient way to make the solar panel. Moreover, the electrodes of the solar panel can be disposed on the substrate or in the layers of material printed onto the substrate. Because the electrodes are thus not located on the face of the solar panel, the electrodes do not block light at the face of the solar panel. In addition, in some embodiments, the layers of the materials printed on the substrate can be disposed in patterns that form diodes (e.g., clamping and/or by-pass diodes) and/or other circuit elements in the solar panel. In some embodiments, a concentrator lens for magnifying and/or directing light into the solar panel can be formed by printing additional material on the face of the solar panel. In some embodiments, the face of the solar panel can include a plurality of angled surfaces at least some of which can be oriented at different angles.

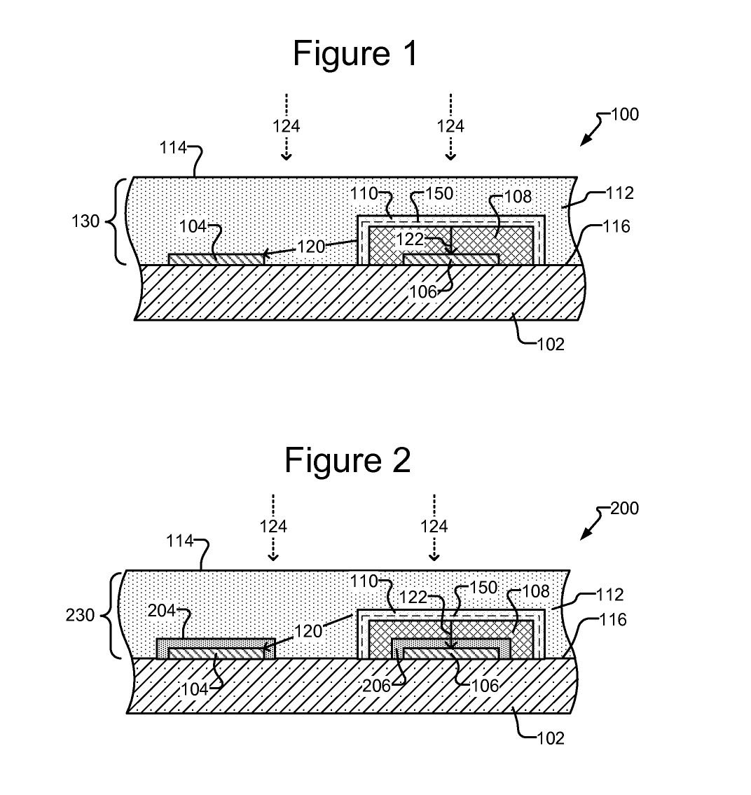

FIG. 1 illustrates a partial, side view of a non-limiting example of a solar panel 100 according to some embodiments of the invention. As shown, solar panel 100 can include a substrate 102 with a cathode electrode 104 and an anode electrode 106, which can be disposed on a surface 116 of the substrate. The solar panel 100 can also include layers 130 of different materials. As shown, layers 130 can include a P region 108 (which can be a non-limiting example of a first region) comprising a material with P-doped semiconductor particles (e.g., the particles can be doped to have an excess of holes). The semiconductor particles can comprise silicon and can be nano-particles. As shown in FIG. 1, P region 108 can be disposed on surface 116 of substrate 102 and on and partially or completely around anode electrode 106. The layers 130 of materials can also include an N region 112 (which can be a non-limiting example of a second region) comprising a material with N-doped semiconductor particles (e.g., the particles can be doped to have an excess of electrons). The semiconductor particles can comprise silicon and can be nano-particles. As shown in FIG. 1, the N region 112 can be disposed on surface 116 of substrate 102 and on and partially or completely around cathode electrode 104 and P region 108. Alternatively, the cathode electrode 104 and the anode electrode 106 can be located within the layers 130. For example, rather than directly on the surface 116, the cathode electrode 104 can be spaced apart from the surface 116 and thus embedded in the N region 112. The anode electrode 106 can also be spaced apart from the surface 116 and thus embedded in the P region 108. The cathode electrode 104 and/or the anode electrode 106 can thus be disposed within the layers 130 between an outer layer (e.g., the face 114) and the surface 116 of the substrate 102.

A depletion region 110 forms at the junction 150 between the P region 108 and the N region 112. Light 124 striking a face 114 (e.g., an outer layer of layers 130) of the solar panel 100 can generate free electron and hole pairs at the surface and within the layers 130 (which comprise semiconductor material) and produce a flow of electrons 120 from the depletion region 110 to the cathode electrode 104 and a corresponding flow of holes 122 from the depletion region 110 to the anode electrode 106. Thus, when the solar panel 100 is connected to a load, light 124 striking face 114 can generate an electrical current which flows out of P region 108, through anode 106, through the load, and back into cathode 104, and into N region 112.

The substrate 102 can be any structure capable of supporting electrodes 104 and 106 and layers 130. In some examples, substrate 102 can be opaque or partially transparent, and the surface 116 of the substrate 102 can be flat or curved. Alternatively, substrate 102 can be transparent or partially transparent. Structurally, substrate 102 can be, for example, a block of a non-conductive material. Alternatively, substrate 102 can be a portion of a building structure, such as a roof of a building. In some examples, substrate 102 can be a portion of a machine such as a non-conductive panel on a body of an automobile.

Electrodes 104 and 106 can be made of any electrically conductive material. For example, electrodes 104 and 106 can comprise electrically conductive material (e.g., metal) disposed as traces on substrate 102. As another example, electrodes 104 and 106 can be a material comprising electrically conductive particles (e.g., nano-particles of metal or another electrically conductive material). As will be seen, in some examples, the material that forms electrodes 104 and 106 can be a liquid solution suitable for printing through a print head, painted, or otherwise deposited or applied to substrate 102 in liquid form and then hardened to form a conductive trace.

In some embodiments, the material that forms P region 108 can be a liquid material in which P-doped semiconductor particles are suspended. In some embodiments, the P region 108 can comprise P-doped semiconductor material (e.g., silicon). For example, the P region 108 can be a semiconductor material doped with boron in a concentration of about 1×10¹⁴ to 1×10¹⁶ atoms per cubic centimeter. Rather than boron, other dopants can be used. For example, gallium or other Group III elements from the Periodic Table can be used. (Group III elements are elements in column III of the Periodic Table.) To facilitate deposition of the P region 108, the material deposited to form the P region 108 can initially be in liquid form. For example, the nano-particle material deposited to form the P region 108 can be deposited in the form of a liquid (e.g., water) in which nano-particles of doped silicon (e.g., doped with boron in a concentration of about 1×10¹⁴ to 1×10¹⁶ atoms per cubic centimeter) are suspended. In some embodiments, the nano-particles can have diameters ranging from 5 nanometers to 50 nanometers and can be suspended in the liquid in concentrations of about 30 milligrams to 70 milligrams of nano-particles particles to 30 milliliters of liquid. In some embodiments, the nano-particles can have diameters in the foregoing range and can be suspended in the liquid in concentrations of about 50 milligrams of nano-particles particles to 30 milliliters of liquid. The foregoing ranges and numerical values are examples only, and concentrations, weights, etc. can be outside of those ranges or different than those values.

In some embodiments, the material that forms N region 112 can also be a liquid material in which N-doped semiconductor particles are suspended. In some embodiments, the N region 112 can comprise N-doped semiconductor material (e.g., silicon). For example, the N region 112 can be semiconductor material doped with phosphorus in a concentration of about 1×10¹⁴ to 1×10¹⁶ atoms per cubic centimeter. Rather than phosphorus, other dopants can be used. For example, arsenic or other Group V elements from the Periodic Table can be used. (Group V elements are elements in column V of the Periodic Table.) To facilitate deposition of the N region 112, the material deposited to form the N region 112 can initially be in liquid form. For example, the material deposited to form the N region 112 can be deposited in the form of a liquid (e.g., water) in which nano-particles of doped silicon (e.g., doped with phosphorus in a concentration of about 1×10¹⁴ to 1×10¹⁶ atoms per cubic centimeter) are suspended. In some embodiments, the nano-particles can have diameters ranging from 5 nanometers to 50 nanometers and can be suspended in the liquid in concentrations of about 30 milligrams to 70 milligrams of nano-particles particles to 30 milliliters of liquid. In some embodiments, the nano-particles can have diameters in the foregoing range and can be suspended in the liquid in concentrations of about 50 milligrams of nano-particles particles to 30 milliliters of liquid. The foregoing ranges and numerical values are examples only, and concentrations, weights, etc. can be outside of those ranges or different than those values.

As will be seen, the materials that form P region 108 and N region 112 can be printed (e.g., through a print head), painted, or otherwise deposited or applied to substrate 102 in liquid form and then hardened to form the P region 108 and N region 112.

Solar panel 100 is exemplary only, and many modifications are possible. FIG. 2 illustrates a non-limiting example of a solar panel 200 that can be a modification of the solar panel 100 of FIG. 1 according to some embodiments of the invention. As shown in FIG. 2, solar panel 200 can be generally similar to solar panel 100 except that layers 230 can include, in addition to P region 108 and N region 112, an N+ region 204 (which can be a non-limiting example of a third region) and a P+ region 206 (which can be a non-limiting example of a fourth region).

The N+ region 204 can comprise material that can be generally similar to the material that forms the N region 112 except that the N+ region 204 can have a greater concentration of N doping than the material that forms the N region 112. In some embodiments, the material that forms the N+ region 204 can be a liquid material in which N-doped semiconductor particles are suspended. In some embodiments, the N+ region 204 can comprise N-doped semiconductor material (e.g., silicon). For example, the N+ region 204 can be doped with phosphorus in a concentration of greater than about 1×10²⁰ atoms per cubic centimeter. To facilitate deposition of the N+ region 204, the material deposited to form the N+ region 204 can initially be in liquid form. For example, the material deposited to form the N+ region 204 can be deposited in the form of a liquid (e.g., water) in which nano-particles of doped silicon (e.g., doped with phosphorus in a concentration of greater than about 1×10²⁰ atoms per cubic centimeter) are suspended. In some embodiments, the nano-particles can have diameters ranging from 5 nanometers to 50 nanometers and can be suspended in the liquid in concentrations of about 30 milligrams to 70 milligrams of nano-particles particles to 30 milliliters of liquid. In some embodiments, the nano-particles can have diameters in the foregoing range and can be suspended in the liquid in concentrations of about 50 milligrams of nano-particles particles to 30 milliliters of liquid. The foregoing ranges and numerical values are examples only, and concentrations, weights, etc. can be outside of those ranges or different than those values.

Similarly, the P+ region 206 can comprise material that can be generally similar to the material that forms P region 108 except that P+ region 206 can have a greater concentration of P doping than the material that forms P region 108. In some embodiments, the material that forms the P+ region 206 can be a liquid material in which P-doped semiconductor particles are suspended. In some embodiments, the P+ region 206 can comprise P-doped semiconductor material (e.g., silicon). For example, the P+ region 206 can be semiconductor material doped with boron in a concentration of greater than about 1×10²⁰ atoms per cubic centimeter. To facilitate deposition of the P+ region 206, the material deposited to form the P+ region 206 can initially be in liquid form. For example, the material deposited to form the P+ region 206 can be deposited in the form of a liquid (e.g., water) in which nano-particles of doped silicon (e.g., doped with boron in a concentration of greater than about 1×10²⁰ atoms per cubic centimeter) are suspended. In some embodiments, the nano-particles can have diameters ranging from 5 nanometers to 50 nanometers and can be suspended in the liquid in concentrations of about 30 milligrams to 70 milligrams of nano-particles particles to 30 milliliters of liquid. In some embodiments, the nano-particles can have diameters in the foregoing range and can be suspended in the liquid in concentrations of about 50 milligrams of nano-particles particles to 30 milliliters of liquid. The foregoing ranges and numerical values are examples only, and concentrations, weights, etc. can be outside of those ranges or different than those values. As will be seen, the material that forms the N+ region 204 and the P+ region 206 can be printed (e.g., through a print head), painted, or otherwise deposited or applied to substrate 102 in liquid form and then hardened to form the N+ region 204 and the P+ region 206.

As shown, N+ region 204 can be disposed on surface 116 of substrate 102 and on and partially or completely around the cathode electrode 104, and the P+ region 206 can be disposed on the surface 116 of the substrate 102 and on and partially or completely around the anode electrode 106. As also shown, P region 108 can be disposed on surface 116 of substrate 102 and on and partially or completely around P+ region 206. Because the P+ region 206 is disposed partially or completely around the anode electrode 106 in the example shown in FIG. 2, the P region 108 can be considered to also be disposed partially or completely around the anode electrode 106. As also shown, N region 112 can be disposed on surface 116 of substrate 102 and on and partially or completely around P region 108 and on and partially or completely around N+ region 204. Because the N+ region 204 is disposed partially or completely around the cathode electrode 104 in the example shown in FIG. 2, the N region 112 can be considered to also be disposed partially or completely around the cathode electrode 104. As noted above, depletion region 110 forms at the junction 150 between P region 108 and N region 112.

Consistent with the discussion of FIG. 1, the cathode electrode 104 and the anode electrode 106 can alternatively be located within the layers 230. For example, rather than directly on the surface 116, the cathode electrode 104 can be spaced apart from the surface 116 and thus embedded in the N+ region 204. The anode electrode 106 can also be spaced apart from the surface 116 and thus embedded in the P+ region 206. The cathode electrode 104 and/or the anode electrode 106 can thus be disposed within the layers 230 between an outer layer (e.g., the face 114) and the surface 116 of the substrate 102.

Regardless of whether the electrodes 104 and 106 are on or spaced away from the surface 116, the N+ region 204 and P+ region 206 can prevent or reduce the Schottky effect. Otherwise, solar panel 200 can function generally like solar panel 100. For example, light 124 striking a face 114 of the solar panel 200 can cause a flow of electrons 120 from depletion region 110 to cathode electrode 104 and a corresponding flow of holes 122 from depletion region 110 to anode electrode 106. Thus, light 124 striking face 114 can generate an electrical through cathode electrode 104 and anode electrode 106 when connected to an electrical element to complete a circuit.

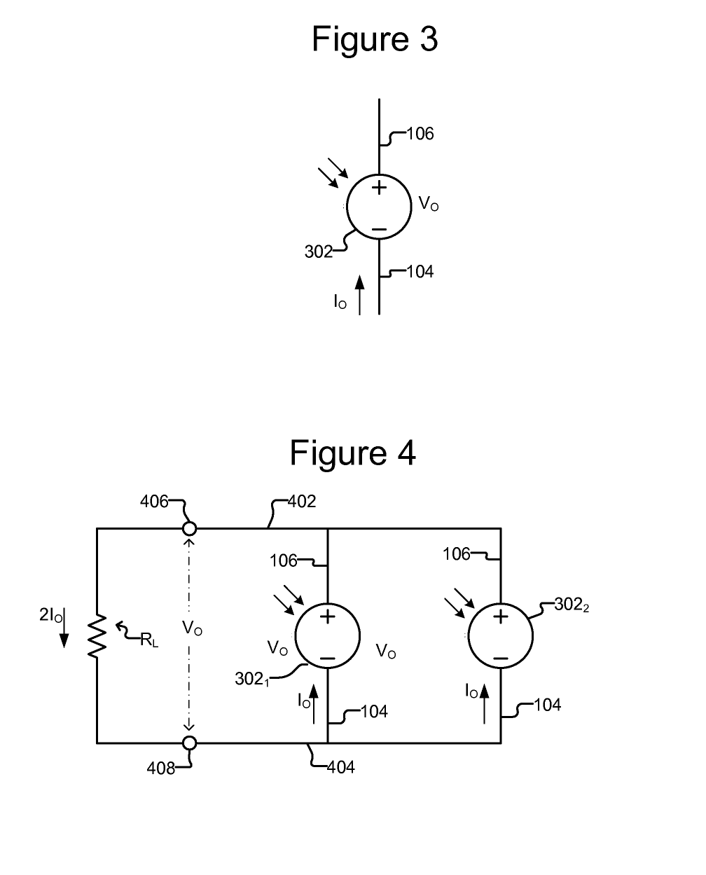

In the examples shown in FIGS. 1 and 2, a solar cell can be formed between the cathode electrode 104 and the anode electrode 106. FIG. 3 illustrates a schematic circuit diagram of such a solar cell. As can be seen, the schematic circuit can include a current source 302 that outputs current I_{O} (and voltage V_{O}) when a load (not shown in FIG. 3) is connected to the cathode electrode 104 and the anode electrode 106. Two or more such solar cells can be made on substrate 102, and the solar cells can be connected in series or parallel. FIG. 4 illustrates an exemplary schematic diagram in which two such solar cells are connected in parallel. As shown, the anode electrode 106 of a first solar cell represented by current source 302₁ can be connected to a first connector 402, which can be connected to a first terminal 406. The cathode electrode 104 of the first solar cell can be connected to a second electrically conductive connector 404, which can be connected to a second terminal 408. Resistor R_{L} in FIG. 4 can represent a load connected between the terminals 406 and 408. The anode electrode 106 of a second solar cell represented by current source 302₂ can also be connected to the first connector 402, and the cathode electrode 104 of the second solar cell can be connected to the second connector 404. As also shown, the currents I_{O} output by the two solar cells can combine to produce a current output that can be the sum of the individual current outputs of each solar cell. In the non-limiting example shown in FIG. 4, two solar cells are connected in parallel; the current output at terminal 406 can thus be two times (2I_{O}) the current output of each solar cell (each of which is shown in FIG. 4 as outputting current I_{O}). More than two solar cells, however, can be connected in parallel in FIG. 4. The voltage across terminals 406 and 408 is V_{O}.

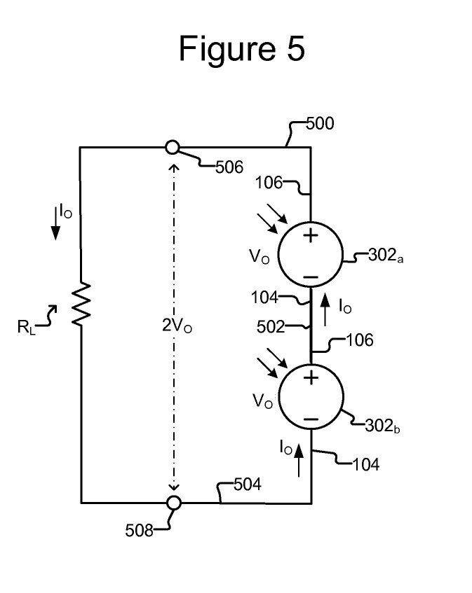

FIG. 5 illustrates an exemplary schematic diagram in which two solar cells are connected in series. As shown, the anode electrode 106 of a first solar cell represented by current source 302ₐ can be connected to a first connector 500, which can be connected to a first terminal 506. The cathode electrode 104 of the first solar cell can be connected to a second electrically conductive connector 502. The anode electrode 106 of a second solar cell represented by current source 302_{b} can also be connected to the second connector 502, and the cathode electrode 104 of the second solar cell can be connected to a third connector 504, which can be connected to a second terminal 508. Resistor R_{L} in FIG. 5 can represent a load connected between the terminals 506 and 508. As also shown, the voltage V_{O} output by the two solar cells can combine to produce a voltage output across the first terminal 506 and the second terminal 508 that can be the sum of the individual voltage output V_{O} output by each solar cell. In the non-limiting example shown in FIG. 5, two solar cells are connected in parallel; the voltage output between the terminal 506 and the terminal 508 can be two times (2V_{O}) the voltage output by each solar cell (each of which is shown in FIG. 5 as outputting voltage V_{O}). More than two solar cells, however, can be connected in series in FIG. 5. The current through terminals 506 and 508 is I_{O}.

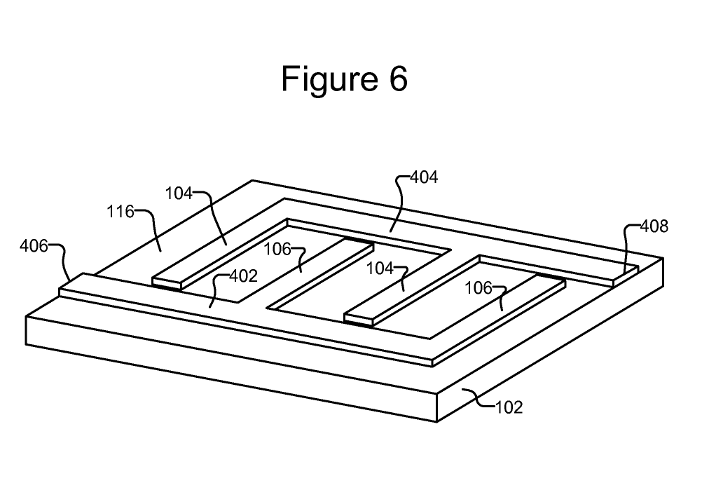

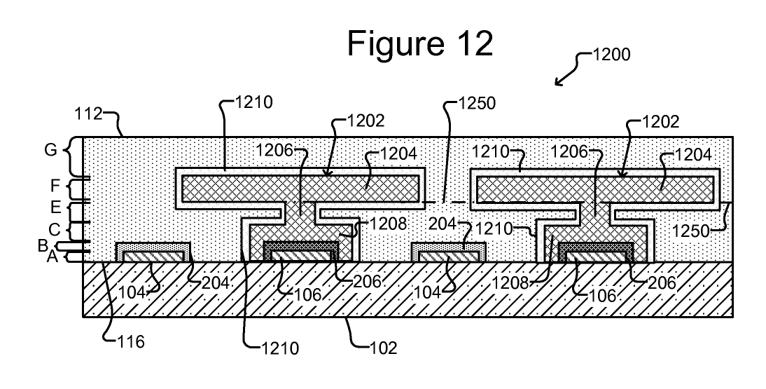

FIGS. 6-11B illustrate an exemplary process for making a solar panel like solar panel 200. For ease of discussion and illustration, the process is illustrated in FIGS. 6-11B as making solar panel 200 with two solar cells connected in parallel as shown in FIG. 4, but the process can be used to make solar panel 200 with more than two solar cells connected in parallel or solar cells (any number) connected in series as shown in FIG. 5. The process illustrated in FIGS. 6-11 can also be used to make any of the solar panels illustrated herein include solar panel 100 or any of the solar panels 1200, 1300, 1400, 1500, 1700, 1900, 2000, and 2100 in FIGS. 12, 13, 14A, 15, 17, 19, 20, and 21.

FIG. 6 illustrates substrate 102 with two sets of cathode electrodes 104 and anode electrodes 106 on a surface 116 of substrate 102. As also shown, connectors 404 and 402 in the form of electrically conductive traces can be provided on the surface 116 of the substrate 102, and the terminals 406 and 408 can be provided as the ends of the traces. As will be seen, a solar cell can be formed between each pair of cathode 104 and anode 106 electrodes. In FIG. 6, the two solar cells are connected in parallel (as depicted in FIG. 4). Thus, each cathode 104 can be connected to connector 404, which can be connected to terminal 408, and each anode 106 can be connected to connector 402, which can be connected to terminal 406.

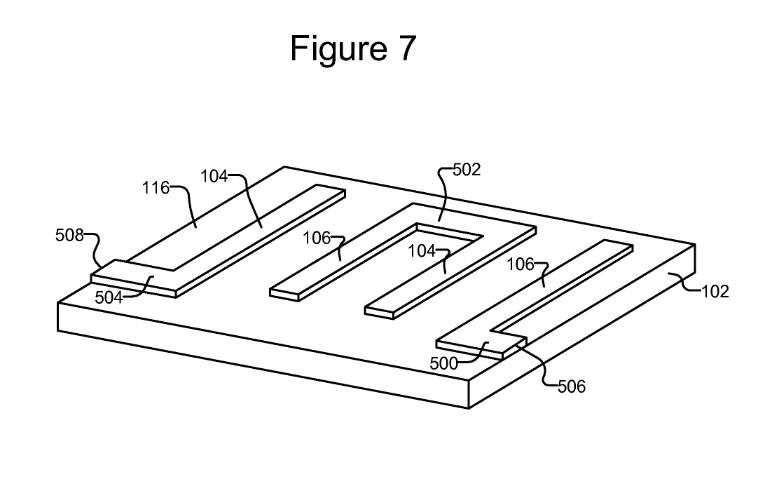

FIG. 7 illustrates substrate 102 with cathode electrodes 104, anode electrode 106, connectors 500, 502, and 504 in the form of electrically conductive traces on the surface 116 of the substrate. Terminals 506 and 508 can be ends of those traces as shown in FIG. 7. A solar cell can be formed between each pair of cathode 104 and anode 106 electrodes. In FIG. 7, the two solar cells are connected in series (as depicted in FIG. 5). Thus, the anode electrode 106 of the first solar cell is connected to connector 500, which is connected to a terminal 506. The cathode electrode 104 of the first solar cell and the anode electrode 106 of the second solar cell are connected to connector 502, and the cathode electrode 104 of the second solar cell is connected to connector 504, which is connected to terminal 508.

Regardless of whether anode and cathode electrodes, traces, and terminals are as shown in FIG. 6 or FIG. 7, substrate 102 can be any structure that can support layers 230 (see FIG. 2). Non-limiting examples of substrate 102 include a ceramic substrate, an organic substrate, or a printed circuit board. Alternatively, substrate 102 can be a portion of a non-conductive surface of a structure or an apparatus. For example, substrate 102 can be a portion of a roof, outside wall, or other portion of a building or other structure. As another example, substrate 102 can be an outside portion of a body of an automobile. As yet another example, substrate 102 can be a part of a machine. Whether substrate 102 is a standalone structure or a part of another structure or building, surface 116 of substrate 102 need not flat but can be curved and/or can include discontinuities.

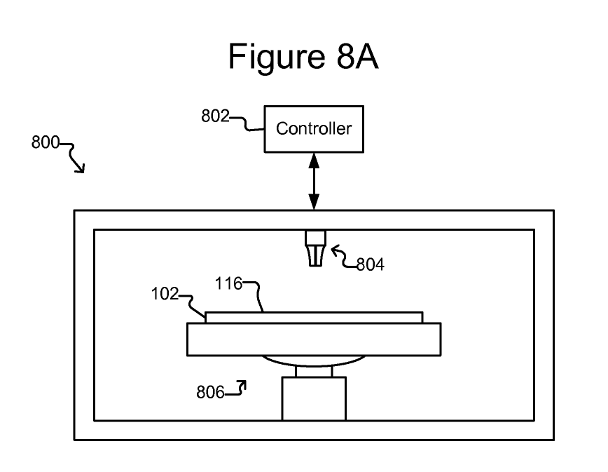

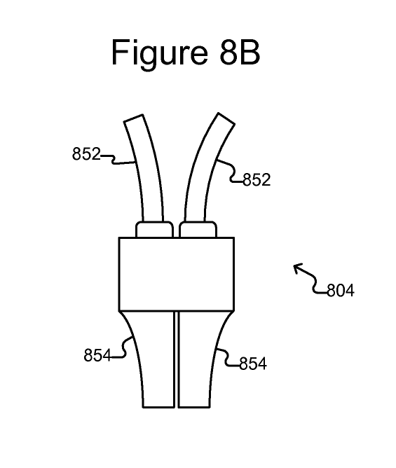

Substrate 102 can be obtained with electrodes 104 and 106, connectors 402 and 404 or 500, 502, and 504, and terminals 406 and 408 or 506 and 508. For example, substrate 102 can be a block of non-conductive material, and electrodes 104 and 106, connectors 402 and 404 or 500, 502, and 504, and terminals 406 and 408 or 506 and 508 can comprise electrically conductive traces on surface 116 of substrate 102. Alternatively, electrodes 104 and 106, connectors 402 and 404 or 500, 502, and 504, and terminals 406 and 408 or 506 and 508 can be formed on surface 116 of substrate 102. For example, as discussed above, a material comprising a liquid solution with suspended electrically conductive nano-particles can be deposited on surface 116 of substrate to form electrodes 104 and 106, connectors 402 and 404 or 500, 502, and 504, and terminals 406 and 408 or 506 and 508. The material can be deposited on surface 116 through a nozzle (e.g., an ink jet print head). For example, substrate 102 can be placed on a stage 806 in a printing apparatus 800 that includes a print head 804 as generally shown in FIG. 8A. As shown in FIG. 8B, print head 804 can include multiple nozzles 854 each of which can be fed by a different supply tube 852 with a different material. Although two nozzles 854 and supply tubes 852 are shown, more can be included. Different materials can thus be deposited on substrate 102 through print head 804. Referring again to FIG. 8A, stage 806 and/or print head 804 can be moveable so that print head 804 can be selectively positioned with respect to substrate 102. A controller 802 can control positioning of stage 806 and/or print head 804 and dispensing of materials through print head 804.

Alternatively, material can be deposited on the surface 116 of the substrate 102 through another type of nozzle or dispensing mechanism (not shown). As yet another alternative, material can be deposited on surface 116 of substrate 102 by brushing, rolling, or otherwise applying the material to surface 116. Once applied to surface 116, the material can be cured or otherwise hardened or activated to form conductive traces. For example, the material can be heated. For example, the material can be heated using a heat gun. As another example, the material can be heated using the mechanism used to apply the material to surface 116. In some embodiments, the material can be heated to 150-250 degrees Celsius. In some embodiments, the material can be heated to 150-200 degrees Celsius. The foregoing heating ranges are exemplary only, and the material can be heated in some embodiments to a temperature that is less than 150 or greater than 250 degrees Celsius.

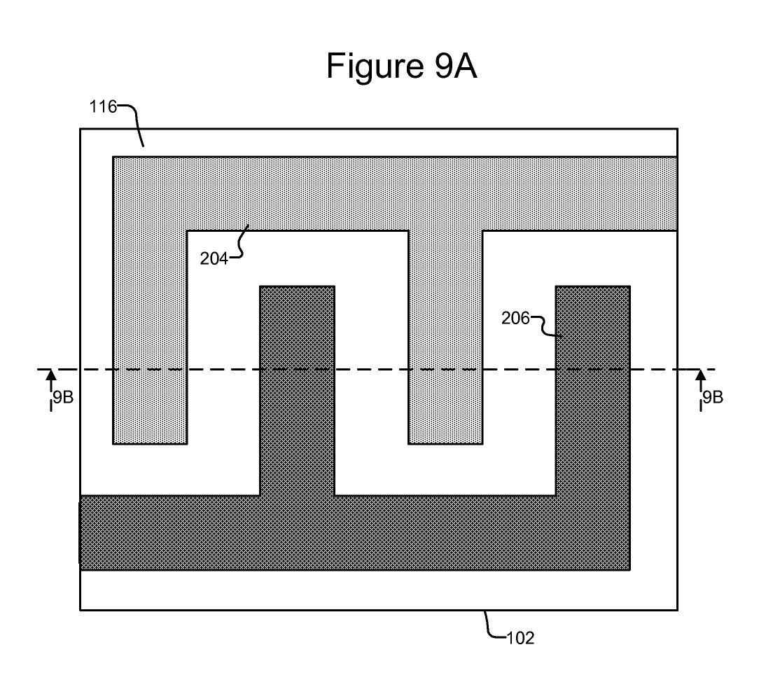

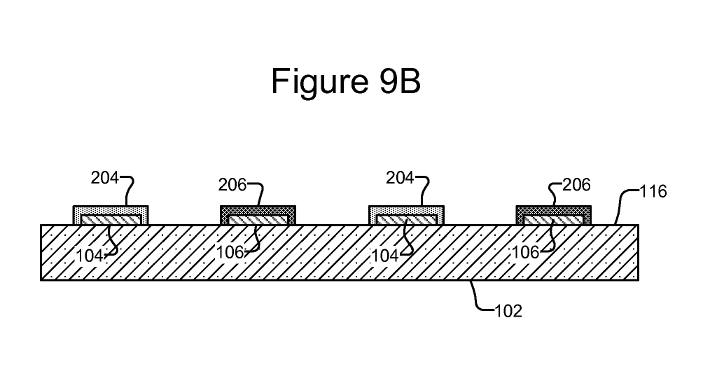

Regardless of whether anode and cathode electrodes, connectors, and terminals are as shown in FIG. 6 or FIG. 7, the solar cells can be made as illustrated in FIGS. 9A-11B. As mentioned above, for ease of discussion and illustration, FIGS. 9A-11B illustrate fabrication on the cathode electrodes 104, anode electrodes 106 and connectors 402 and 404 as shown in FIG. 6.

As shown in FIGS. 9A and 9B, N+ material that forms N+ region 204 can be deposited on surface 116 of substrate 102 and on and partially or completely around cathode electrode 104. Optionally, the N+ material that forms N+ region 204 can also be deposited onto connector 404 as shown in FIG. 9A. As discussed above, N+ material can be a liquid solution (e.g., the liquid solution for N+ material discussed above). The N+ material can be deposited using any of the techniques discussed above for depositing the material that forms electrodes 104 and 106. For example, as discussed above, N+ material can comprise a liquid in which N-doped semiconductor particles are suspended, and the N+ material can be deposited on substrate 102 using printing apparatus 800 of FIGS. 8A and 8B. Alternatively, N+ material that forms N+ region 204 can be a different material and/or deposited using a different type of dispensing mechanism or brushed or rolled onto surface 116 and cathode electrode 104.

Once applied or deposited as shown in FIGS. 9A and 9B, the N+ material that forms N+ region 204 can be cured or otherwise hardened or activated to form the N+ region 204. For example, the material can be heated. For example, the material can be heated using a heat gun. As another example, the material can be heated using the mechanism used to apply the material to surface 116. In some embodiments, the material can be heated to 150-250 degrees Celsius. In some embodiments, the material can be heated to 150-200 degrees Celsius. The foregoing heating ranges are exemplary only, and the material can be heated in some embodiments to a temperature that is less than 150 or greater than 250 degrees Celsius.

As also shown in FIGS. 9A and 9B, P+ material that forms P+ region 206 can be deposited on surface 116 of substrate 102 and on and partially or completely around anode electrodes 106. Optionally, the P+ material that forms P+ region 206 can also be deposited onto connector 402. As discussed above, P+ material can be a liquid solution. For example, as discussed above, P+ material can comprise a liquid in which P-doped semiconductor particles are suspended. P+ material that forms P+ region 206 can be deposited and cured generally in the same or similar way as N+ material that forms N+ region 204 as discussed above.

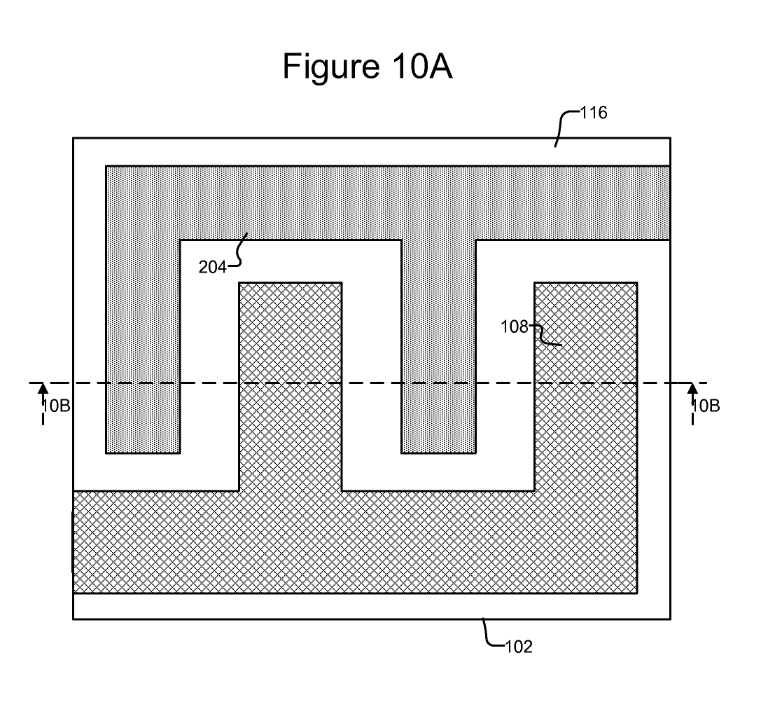

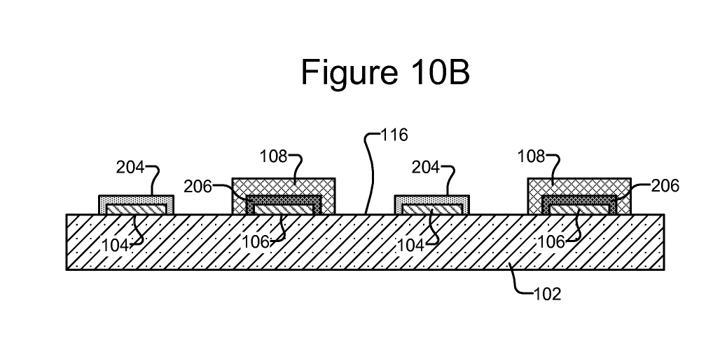

As shown in FIGS. 10A and 10B, P material that forms P region 108 can be deposited on surface 116 of substrate 102 and on and partially or completely around P+ region 206 and thus effectively partially or completely around anode electrode 106. Optionally, the material that forms P region 108 can also be deposited on P+ region formed partially or completely around connector 402 as shown in FIG. 10A. As discussed above, P material can be a liquid solution. For example, as discussed above, P material can comprise a liquid in which P-doped semiconductor particles are suspended. P material that forms P region 108 can be deposited and cured generally in the same or similar way as N+ material that forms N+ region 204 as discussed above.

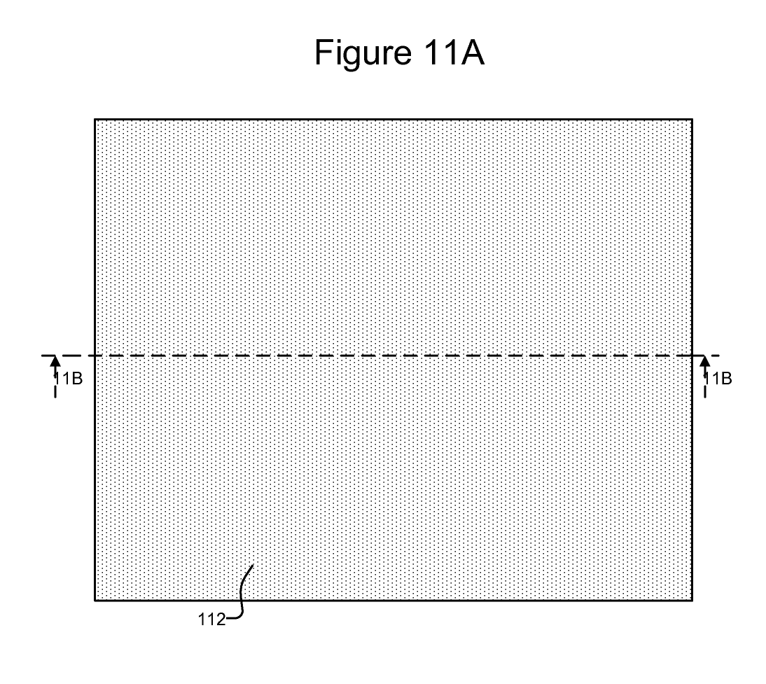

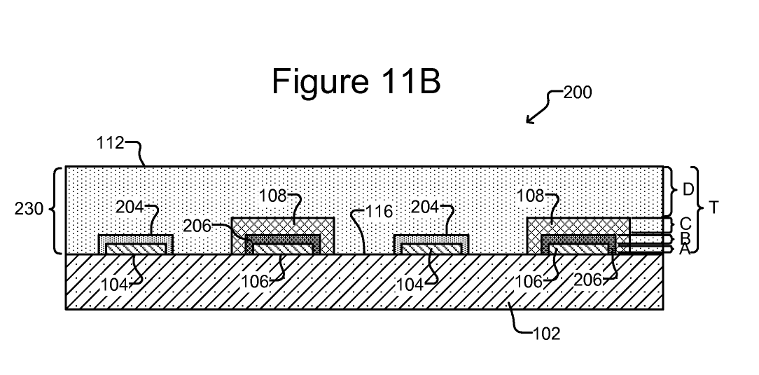

As shown in FIGS. 11A and 11B, N material that forms N region 112 can be deposited on the surface 116 of substrate 102 and on and partially or completely around N+ region 204 and thus effectively partially or completely around cathode electrode 104. As discussed above, N material can be a liquid solution. For example, as discussed above, N material can comprise a liquid in which N-doped semiconductor particles are suspended. As shown, N material that forms N region 112 can also be deposited on and partially or completely around P region 108. N material that forms N region 112 can be deposited and cured generally in the same or similar way as N+ material that forms N+ region 204 as discussed above.

Referring to FIG. 11B, in some embodiments, a thickness A of the cathode electrode 104 and the anode electrode 106 can be about 0.5 to 2 microns; a thickness B of the P+ regions 206 on the anode electrodes 106 and the N+ regions 204 on the cathode electrodes 104 can be about 0.5 to 2 microns; a thickness C of the P regions 108 on the P+ regions 206 can be about 1 to 4 microns; and a thickness D of the N region 112 on the P regions 108 can be about 1 to 4 microns. In such embodiments, the thickness T of the layers 230 can thus be about 3 to 12 microns. In other embodiments, a thickness A of the cathode electrode 104 and the anode electrode 106 can be about 1 micron; a thickness B of the P+ regions 206 on the anode electrodes 106 and the N+ 204 regions on the cathode electrodes 104 can be about 1 micron; a thickness C of the P regions 108 on the P+ regions 206 can be about 2 to 3 microns; and a thickness D of the N region 112 on the P regions 108 can be about 2 to 3 microns. In such embodiments, the thickness T of the layers 230 can thus be about 6 to 8 microns. All of the foregoing numerical ranges for thicknesses A, B, C, D, and T are examples only, and each of the thicknesses A, B, C, D, and T can be outside of the foregoing ranges in some embodiments.

Although not shown in the Figures, if a solar panel is to be made on the substrate 102 with the cathode electrodes 104, anode electrodes 106, connectors 500, 502, and 504, and terminals 506 and 508 of FIG. 7: material forming N+ region 204 can be deposited onto the cathode electrodes 104 and optionally onto connectors 500 and 504, and material forming P+ region 206 can be deposited onto the anode electrodes 106 and optionally connector 502; material forming P region 108 can then be deposited onto the P+ regions 206; and material forming the N region 112 can be deposited onto the foregoing regions.

In some embodiments, the process illustrated in FIGS. 6-11B and solar panel 200 (or any of the solar panels 100, 1200, 1300, 1400, 1500, 1700, 1900, 2000, and 2100) produced by that process or a similar process can provide advantages. For example, the cathode electrode 104 and the anode electrode 106 can be on the surface 116 of substrate 102, and terminals 406 and 408 or terminals 506 and 508 (see FIGS. 6 and 7) can also be on the surface 116 of the substrate 102. In some embodiments, the surface 116 of the substrate 102 can be a convenient location from which to connect terminals 406 and 408 or 506 and 508 (or electrodes 104 and 106) to other electric devices (not shown), such as batteries or electronic devices to be powered by solar panel 200. As should be apparent, terminals 406 and 408 or terminals 506 and 508, connectors 402 and 404 or connectors 500, 502, and 504, and cathode electrodes 104 and anode electrodes 106 are not, for example, on the face 114 of the layers 230. This can be advantageous in that terminals 406 and 408 or terminals 506 and 508, connectors 402 and 404 or connectors 500, 502, and 504, and cathode electrodes 104 and anode electrodes 106 will not block or interfere with light 124 striking the face 114. As noted above with respect to FIGS. 1 and 2, the electrodes 104 and 106 can be embedded within the layers 230 rather than on the surface 116 of the substrate 102. The connectors 402, 404, 500, 502, and 504 can likewise be embedded within the layers 230. It is noted that the advantage of not having electrodes or other electrical connectors on the face 114 is still achieved. As another example of an advantage provided by the process illustrated in FIGS. 6-11B, the ability to form layers 230 by printing the materials of layers 230 on substrate 102 can increase the speed and efficiency of making solar panels like solar panels 200. As yet another advantage, the ability to form layers 230 by brushing or rolling the materials of layers 230 on substrate 102 can allow layers 230 to be applied to substrate 102 even if the surface 116 of the substrate 102 is uneven, curved, or includes discontinuities. As discussed above, the surface 116 of the substrate 102 need not be flat, but can be uneven, curved, or include discontinuities. In fact, as mentioned, the substrate 102 can be a part of a structure (e.g., a roof of a building) or a part of a machine (e.g., a part of a body of an automobile). The foregoing advantages, as well as other advantages, can be provided by some embodiments of the invention. The invention is not, however, limited to embodiments that provide the foregoing specific advantages.

As mentioned, the process illustrated in FIGS. 6-11B is exemplary only, and variations are possible. For example, the process can be used to make the solar panel 100 of FIG. 1 by not forming N+ region 204 and P+ region 206 (e.g., skipping the part of the process shown in FIGS. 9A and 9B). FIGS. 12-22 illustrate examples of additional such variations.

FIG. 12 illustrates an example of a variation of the process of FIGS. 6-11B and the resulting solar panel 200 illustrated in FIGS. 11A and 11B. As shown, the solar panel 1200 of FIG. 12 can include the substrate 102, which can include the cathode electrodes 104, anode electrodes 106, connectors 402 and 404, and terminals 406 and 408 as shown in FIG. 6 (and can thus include two solar cells connected in parallel as depicted in FIG. 4). Alternatively, the substrate can include the cathode electrodes 104, anode electrodes 106, connectors 500, 502, and 504, and terminals 506 and 508 as shown in FIG. 7 (and can thus include two solar cells connected in series as depicted in FIG. 5). More than two solar cells connected in parallel or series can be formed on substrate 102 and thus included in the solar panel 1200. As also shown, the solar panel 1200 of FIG. 12 can also include N+ regions 204 disposed on the surface 116 of substrate 102 and on and partially or completely around the cathode electrodes 104 and P+ regions 206 disposed on the surface 116 of substrate 102 and on and partially or completely around the anode electrodes 106 like solar panel 200 of FIGS. 11A and 11B. It is noted that the electrodes 104 and 106 can be spaced from the surface 116 of the substrate rather than being on the surface 116 generally as discussed above with respect to FIGS. 1 and 2.

As also shown in FIG. 12, however, the solar panel of FIG. 12 can include a stack 1202 of multi P regions. For example, as shown, each stack 1202 can include a base region 1208, which can be disposed generally where a P region 108 in FIG. 11B is positioned. For example, the base region 1208 of each stack 1202 can be disposed on the surface 116 of the substrate 106 and on and partially or completely around a P+ region 206. Because each base region 1202 is on and partially or completely around a P+ region 206, which is on and partially or completely around an anode electrode 106, each base region 1202 can be considered to be on and partially or completely around an anode electrode 106. The base regions 1208 in FIG. 12 replace the P regions 108 in FIGS. 10A and 10B and can be formed of the same material and in the same way that P regions 108 are formed as illustrated in and discussed above with respect to FIGS. 10A and 10B. Because the base regions 1208 can comprise the same material as the P regions 108, the base regions 1208 are P regions.

As also shown in FIG. 12, each stack 1202 in FIG. 12 can include a neck region 1206 and an upper region 1204. As shown, the upper region 1204 can be shaped generally like the base region 1208 but can be wider (as illustrated in FIG. 12) than the base region 1208. Alternatively, the upper region 1204 can be generally the same width or less wide than the base region 1208. The neck region 1206 can be significantly narrower than the base region 1208 and the upper region 1204. The P material that forms the neck regions 1206 can be deposited on base region 1206. The P material can be the same as the P material that forms the base region, which as discussed above, can be the same as, and can be deposited and hardened like, the material that that forms P regions 108 in FIGS. 10A and 10B. Material forming N region 112 can then be deposited on the surface 116 of substrate 102, on and partially or completely around N+ regions 204 and base regions 1208, and partially or completely around neck regions 1206 up to the upper portion of neck regions 1206 to the line 1250 in FIG. 12. The N region 112 can comprise the same material and can be deposited and hardened the same way as illustrated in FIGS. 11A and 11B and as described above with respect to those figures. P material that forms the upper regions 1204 can be deposited on the N region material at the line 1250 and on the neck regions 1206. The P material that forms upper regions 1204 can be the same and can be deposited and hardened in the same way as the P material that forms the base regions 1208 and the neck regions 1206. Material forming the N region 112 can then be deposited onto the previously deposited material at line 1250 and onto and partially or completely around the upper regions 1204. This material can be the same as and can be deposited and hardened in the same way as the material that forms N region 112 below line 1250 in FIG. 12.

The junction between the stack 1202 and the N region 112 forms a depletion region 1210 as shown in FIG. 12. As should be apparent from comparing FIG. 11B and FIG. 12, the upper region 1204 and the neck region 1206 of each stack 1202 in FIG. 12 can increase substantially the area of the interface between the P regions (of the stack 1202 in FIG. 12) and the N region 112 as compared to the area of the interface between P regions 108 and the N region 112 in FIG. 11B. Generally as discussed above with respect to FIGS. 1 and 2, light striking the upper surface of the N region 112 can generate free electron/hole pairs and produce a flow of electrons from the depletion region 1210 partially or completely around the stack 1202 of FIG. 12 to a cathode electrode 104 and a corresponding flow of holes from the depletion region 1210 to an anode electrode 106. Because of the larger depletion region 1210 in FIG. 12—as compared to the depletion region 110 (see FIGS. 2 and 11B)—more electron/hole pairs and a greater flow of electrons from the depletion region 1210 to an cathode electrode 104 is produced due to the neck region 1206 and the upper region 1204 (which as discussed above, increases the size of the depletion region 1210).

The thickness A of the cathode electrodes 104 and anode electrodes 106 and the thickness B of the N+ regions 204 and the P+ regions 206 on the cathode electrodes 104 and anode electrodes 106 in FIG. 12 can be in the ranges discussed above with respect to FIG. 11B. Likewise, the thickness C of the base regions 1208 on the P+ regions 206 can be in the ranges discussed above for thickness C with respect to FIG. 11B. In some embodiments, a thickness E of the neck regions 1206, a thickness F of the upper regions 1204, and a thickness G of the N region 112 on the upper regions 1204 can each be about 1 to 4 microns. In other embodiments, the thickness E of the neck regions 1206, the thickness F of the upper regions 1204, and the thickness G of the N regions 112 on the upper regions 1204 can each be about 2 to 3 microns. All of the foregoing numerical ranges for thicknesses A, B, C, E, F, and G are examples only, and each of the thicknesses A, B, C, E, F, and G can be outside of the foregoing ranges in some embodiments.

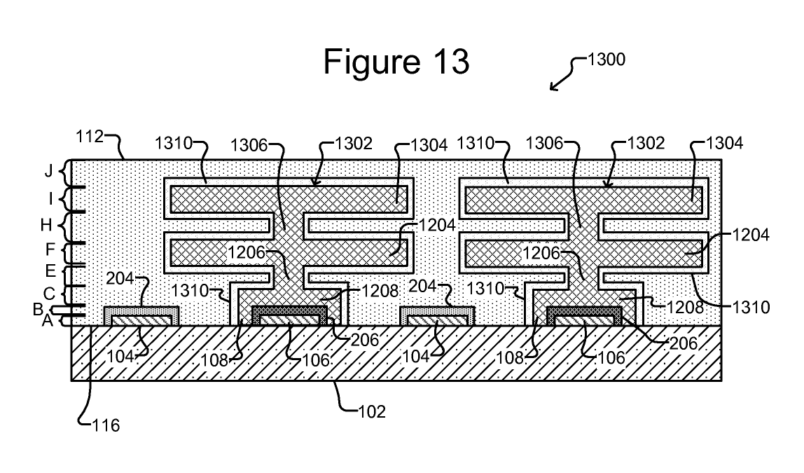

Although each stack 1202 in FIG. 12 includes one upper region 1204, a stack can alternatively include more than one upper region 1204. FIG. 13 illustrates an example of a solar panel 1300 in which a stack 1302 includes two upper regions 1204 and 1304. The solar panel 1300 can be like the solar panel 1200 except that the stack 1302 includes an additional upper region 1304. As shown in FIG. 13, an additional neck region 1306 can be between the upper region 1204 and the additional upper region 1304. The additional neck region 1304 and the additional upper region 1304 can be made of the same material and generally in the same way as the neck region 1206 and the upper region 1204 as discussed above with respect to FIG. 12. Although the stack 1302 is illustrated in FIG. 13 as having two upper regions 1204 and 1304, the stack 1302 can have more than two upper regions (like 1204 and 1304) and additional neck regions (like neck region 1206 or neck region 1306) between adjacent upper regions.

The thicknesses A, B, C, E, and F shown in FIG. 13 (which are also shown in FIG. 12) can be in the ranges discussed above with respect to FIG. 12. In some embodiments, a thickness H of the additional neck regions 1306, a thickness I of the additional upper regions 1304, and a thickness I of the N region 112 on the additional upper regions 1304 can each be about 1 to 4 microns. In other embodiments, the thickness H of the additional neck regions 1306, the thickness I of the additional upper regions 1304, and the thickness J of the N region 112 on the additional upper regions 1304 can each be about 2 to 3 microns. All of the foregoing numerical ranges for thicknesses A, B, C, E, F, H, I, and J are examples only, and each of the thicknesses A, B, C, E, F, H, I, and J can be outside of the foregoing ranges in some embodiments.

Generally in accordance with the discussions above regarding depletions regions, a depletion region 1310 forms at the junction between each stack 1302 and the N region 112. The additional neck region 1306 and the additional upper region 1304 can increase substantially the area of the junction between the P regions (stacks 1302 in FIG. 13) and the N region 112 as compared to the area of the interface between the P regions (stacks 1202 in FIG. 12) and the N region 112 in FIG. 12. The depletion region 1310 can thus be larger than the depletion region 1210. Generally as discussed above with respect to FIG. 12, because of the larger depletion region 1310 in FIG. 13 due to the additional neck region 1306 and upper region 1304, more electron/hole pairs and a greater flow of electrons from the depletion region 1310 to a cathode electrode 104 can be produced.

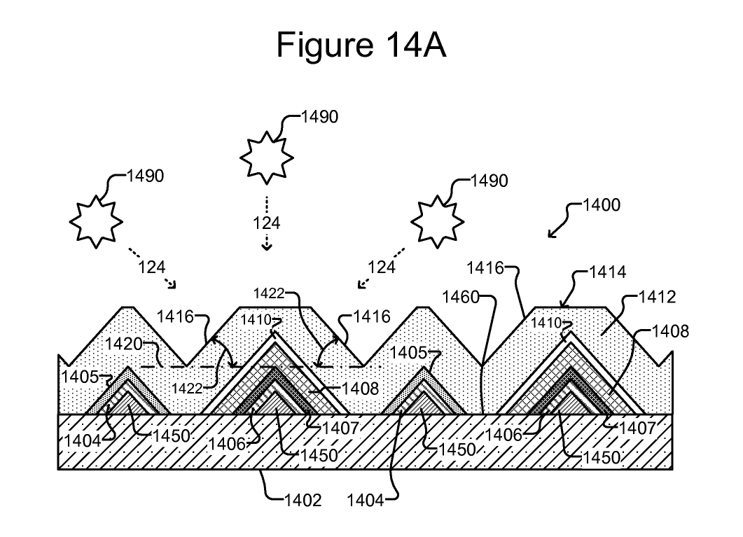

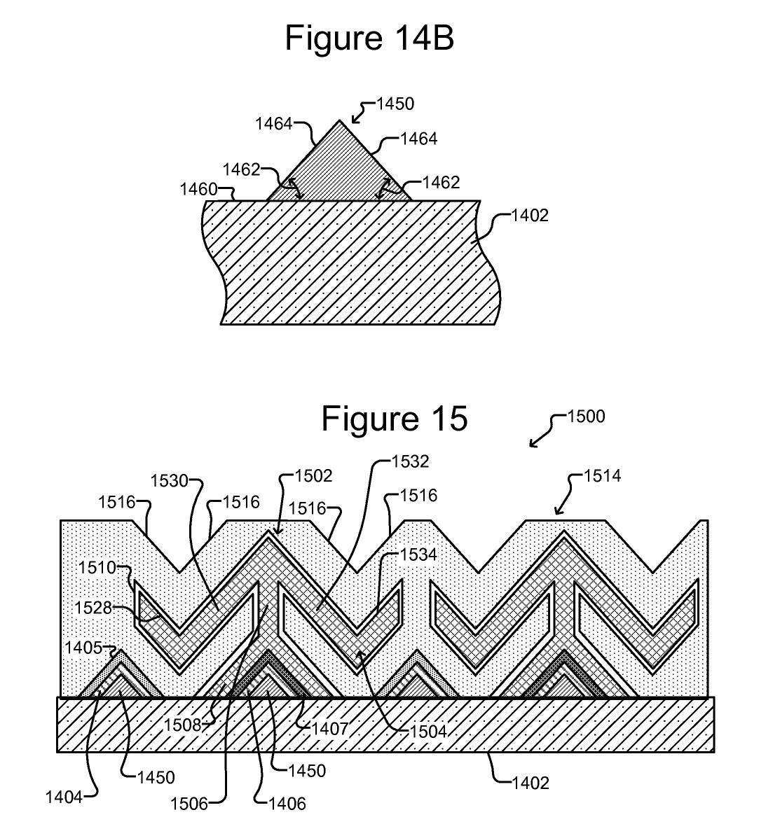

FIG. 14A illustrates another example of a variation of the process of FIGS. 6-11B and the resulting solar panel 200 illustrated in FIGS. 11A and 11B. As shown, the solar panel 1400 of FIG. 14A can include a substrate 1402, which can be like substrate 102 except that substrate 1402 can include bases 1450 with sloped side walls. For example, as shown in FIG. 14B, each base 1450 can have a triangular cross-section as shown in FIG. 14. Side walls 1464 can be angled with respect to the surface 1460 of the substrate 1402. An angle 1462 of each side wall 1464 with respect to the surface 1460 of the substrate 1402 on which the base 1450 is disposed can be the same, substantially the same, or different for each side wall 1464. As will be seen, the angle 1462 of each side wall 1464 can correspond to an angle 1422 of an angled portion 1416 of the face 1414 of the solar panel 1400 (see FIG. 14A). As shown in FIG. 14A, cathode electrodes 1404 and anode electrodes 1406 can be disposed on bases 1450. Although not shown in FIG. 14A, connectors similar to connectors 402 and 404 and terminals similar to terminals 406 and 408 of FIG. 6 can be included on substrate 1402 such that each pair of cathode electrode 1404 and anode electrode 1406 in FIG. 14A forms a solar cell, and the solar cells are electrically connected in parallel as shown in FIG. 4. Alternatively, although also not shown in FIG. 14A, connectors similar connectors 500, 502, and 504 and terminals 506 and 508 of FIG. 7 can be included on substrate 1402 such that each pair of cathode electrode 1404 and anode electrode 1406 in FIG. 14A forms a solar cell, and the solar cells are electrically connected in series as shown in FIG. 5.

As also shown in FIG. 14A, the solar panel 1400 can include N+ regions 1405 disposed on the surface 1460 of the substrate 1402 and on and partially or completely around the cathode electrodes 1404, and the solar panel 1400 can include P+ regions 1407 disposed on the surface 1460 of the substrate 1402 and on and partially or completely around the anode electrodes 1406. As shown, the N+ regions 1405 and the P+ regions 1407 can be angled with respect to surface 1460 of the substrate 1402 generally following the angle 1462 of the sidewalls 1464 of the bases 1450. Otherwise, the N+ regions 1405 can be generally similar to the N+ regions 204 shown in FIGS. 9A and 9B, and the P+ regions 1407 can be generally similar to the P+ regions 206 shown in FIGS. 9A and 9B.

Still referring to FIG. 14A, the solar panel 1400 can include P regions 1408 disposed on the surface 1460 of the substrate 1402 and on and partially or completely around the P+ regions 1407. Because the P+ regions 1407 are on and partially or completely around the anode electrodes 1406, the P regions 1408 can also be considered to be disposed on and partially or completely around the anode electrodes 1406. As shown, the P regions 1408 can be angled with respect to surface 1460 of the substrate 1402 generally following the angle 1462 of the sidewalls 1464 of the bases 1450. Otherwise, the P regions 1408 can be generally similar to the P regions 108 shown in FIGS. 10A and 10B.

The solar panel 1400 can also include an N region 1412 disposed on the surface 1460 of the substrate 1402 and on and partially or completely around the N+ regions 1405 and the P regions 1408 as shown in FIG. 14A. As also shown, the face 1414 of the N region 1412 can include angled portions 1416 that generally correspond to the angled side walls 1464 of the bases 1450. As shown in FIG. 14A, the angled portions 1416 of the face 1414 can be angled 1422 with respect to a line or plane 1420 that is generally parallel with the surface 1460 of the substrate 1402. The angles 1462 of each angled portion 1416 of the face 114 can be the same, substantially the same, or different. Moreover, the angles 1462 can correspond generally to the angles 1462 of the side walls 1464 of the bases 1450.

The angles 1422 of the angled portions 1416 can be selected so that the angled portions 1416 are positioned to receive direct sun light 124 even as the position of the sun 1490—and thus the orientation of the sun 1490 with respect to the solar panel 1400—changes. The face 1414 of the solar panel 1400 can thus receive direct or substantially direct sun light 124 even as the position of the sun 1490 changes as shown in FIG. 14A. This can increase the efficiency of the solar panel 1400 in generating current as compared to a solar panel that does not include angled portions 1416. In some embodiments, angles 1422—as well as angles 1462—can be in the range 20-70 degrees. In other embodiments, the angles 1422 and 1462 can be in the range 30-60 degrees. In some embodiments, the angles 1422 and 1462 can be less than 60 degrees, less than 45 degrees, or less than 30 degrees. The foregoing ranges and values for angles 1422 and 1462 are exemplary only, and other angles can be implemented. Moreover, angles 1422 can but need not be the same as or even substantially the same as angles 1462.

The bases 1450 can be provide with or formed on the substrate 1402. In some embodiments, the bases 1450 can be formed in the substrate 1402 be depositing droplets of material on the substrate 1402 utilizing the system of FIG. 8A. For example, droplets can be deposited onto the substrate 1402 through the pattern forming print head 804 in liquid form and then dried or otherwise cured. Examples of suitable materials that can be used to form the bases 1450 include without limitation polymers, filled polymers, epoxies, and filled epoxies. Fillers can include without limitation carbon nanotubes, metal particles, conductive, or non-conductive particles. By way of example and not limitation fillers can be used to increase electrical conductivity, thermal conductivity, or both, of the bases.

The cathode electrodes 1404 and the anode electrodes 1406 can be made of the same materials and in generally the same way as the cathode electrodes 104 and the anode electrodes 106 in FIGS. 6 and 7 as discussed with respect to those figures. Likewise, the N+ regions 1405, the P+ regions 1407, the P regions 1408, and the N regions 1412 can be made of the same materials and in generally the same way as their counterpart regions (N+ regions 204, P+ regions 206, N regions 108, and N region 112) in FIGS. 9A-11B as discussed with respect to those figures.

FIG. 15 illustrates an example of a variation of the solar panel 1400 of FIG. 14A. Like the solar panel 1400 of FIG. 14A, the solar panel 1500 of FIG. 15 can include the substrate 1402 and bases 1450 on which cathode electrodes 1404 and anode electrodes 1406 are disposed generally as described above with respect to FIG. 14A. Also like the solar panel 1400 of FIG. 14A, N+ regions can be disposed on the surface 1460 of the substrate 1402 and on and partially or completely around the cathode electrodes 1404, and P regions 1407 can be disposed on the surface 1460 of the substrate 1402 and on and partially or completely around the anode electrodes 1406.

Unlike the solar panel 1400 of FIG. 14A, however, the solar panel 1500 of FIG. 15 can include a P region stack 1502. Each stack 1502 can include a base region 1508, a neck region 1506, and an upper region 1504. The base region 1508 can be generally similar to and can be made like the P region 1408 in FIG. 14A. The base region 1508 can be angled like the P region 1408 in FIG. 14A. For example, the base region 1508 can be angled with respect to the surface 1460 of the substrate 1402 at an angle or angles that corresponds to the angles 1462 of the side walls 1464 of the bases 1450 as illustrated in FIG. 14B and discussed above. The neck region 1506 can connect the base region 1508 to the upper region 1504, and the neck region 1506 can be made of the same material and in the same way as base region 1508.

The upper region 1504 can comprise a structure disposed above the base region 1508. In the non-limit example shown in FIG. 15, the upper region 1504 can comprise a first angled portion 1530 and a second angled portion 1532 as illustrated in FIG. 15. The first angled portion 1530 and the second angled portion 1532 can be located above and can be oriented to correspond generally to an orientation of the base region 1508. For example, each of the first angled portion 1530 and the second angled portion 1532 can be oriented to correspond to an angle with respect to the surface 1460 of the substrate 1402 that corresponds generally with an angle of a portion of the base region 1508 as shown in FIG. 15.

As also shown in FIG. 15, each stack 1502 can also include a third angled portion 1528 and a fourth angled portion 1534, which can be located above and oriented to correspond to a portion of an N+ region 1405. For example, each of the third angled portion 1528 and the fourth angled portion 1534 can be oriented to correspond to an angle with respect to the surface 1460 of the substrate 1402 that corresponds generally with an angle of a portion of a N+ region 1405 as shown in FIG. 15. As discussed above, angles with respect to the surface 1450 of the substrate 1402 of the N+ region 1405 can correspond to the angles 1462 of the base 1450 on which the N+ region 1405 is disposed.

Still referring to FIG. 15, the solar panel 1500 can include an N region 1512. The N region 1512 can be deposited or formed in sections. For example, after forming the base regions 1508 and the neck regions 1506, at least the portion of the N region 1512 that is under the upper regions 1504 can be formed, after which the upper regions 1504 can be formed. Thereafter, the remaining portions of the N region 1512 can be formed. The N region 1512 can be made of material that is the same as or similar to the material that forms N region 112 in FIGS. 11A and 11B. Moreover, the N region 1512 can be formed in the same or similar way as the N region 112 in FIGS. 11A and 11B.

As discussed above, a depletion region 1510 forms at the junction between the P region stack 1502 and the N region 1512. Because the junction between the stack 1502 and the N region 1512 is larger in FIG. 15 due primarily to the upper region 1504 than the depletion region 1410 in FIG. 14, the depletion region 1510 in FIG. 15 can be larger than the depletion region 1410 in FIG. 14. For the reasons generally discussed above with respect to FIG. 12, the larger depletion region 1510 can result in greater and/or more efficient current generation in the solar panel 1500. In addition, the face 1514 of the N region 1512 can included angled portions 1516, which can be generally similar to angled portions 1416 of the face 1414 of the solar panel 1400 of FIG. 14A. As discussed above with respect to FIG. 14A, the angles of the angled portions 1516 can be selected so that the angled portions 1516 are positioned to receive direct sun light even as the position of the sun—and thus the orientation of the sun with respect to the solar panel 1500—changes as generally depicted in FIG. 14. The angles selected for angled portions 1516 can be the same as or similar to the angles discussed above with respect to the angled portions 1416 of FIG. 14.

Although each multiple P region stack 1502 in FIG. 15 includes one upper region 1504, the P region stacks 1502 can alternatively include more than one upper region 1504. For example, each stack 1502 can include two, three, or more upper regions 1504 connected one to another by a neck region 1506.

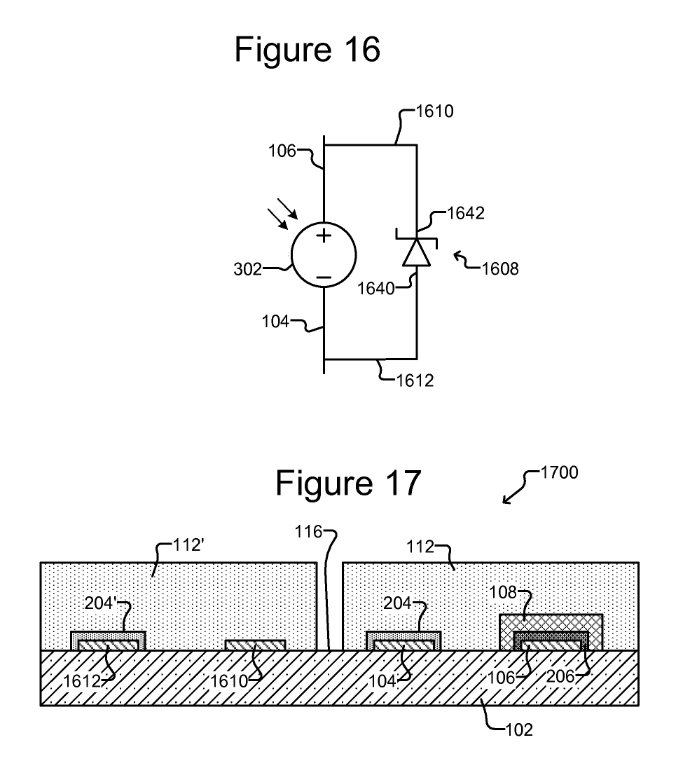

Another non-limiting example of a variation of the process of FIGS. 7-11B involves fabricating electric circuit elements in the layers 230. FIGS. 16-19 illustrate non-limiting examples in which a by-pass diode or a clamping diode is so fabricated.

FIG. 16 illustrates a schematic diagram in which a by-pass diode 1608 (e.g., a Schottky diode) is connected in parallel with a current source 302, which as discussed above, represents a solar cell formed between a cathode electrode 104 and an anode electrode 106 on substrate 102 in the layers 230 of the solar cell 200 (see FIG. 11B). (For example, a first terminal 1640 of the diode 1608 can be connected through an electrode 1612 to the cathode electrode 104, and a second terminal 1642 of the diode 1608 can be connected through an electrode 1610 to the anode electrode 104.) As discussed above, in normal operation, current source 302 can output a current through the cathode electrode 104. A problem can arise if the solar cell represented by the current source 302 becomes reverse biased, which can occur, for example, when part of an array of solar cells is shaded from direct light. In such a reverse bias state, the solar cell can be damaged if a current is forced backwards through the solar cell. For example, referring to FIG. 5 in which two current sources 302ₐ and 302_{b} representing two solar cells are connected in series as discussed above, if one of the solar cells (e.g., the solar cell represented by current source 302ₐ) becomes reversed biased, it can be damaged by current output by the other solar cell (e.g., the solar cell represented by current source 302_{b}). The diode 1608 in FIG. 16 can provide a by-pass current path for such current. For example, if the solar cell represented by current source 302 in FIG. 16 becomes reverse biased, the diode 1608 can provide a by-pass current path for current that would otherwise be forced in the wrong current direction into a portion of the solar cell array.

As mentioned, the diode 1608 can be made during the same process as the solar cell is made. FIG. 17 illustrates an example according to some embodiments of the invention. Initially, it is noted that FIG. 17 illustrates a solar panel 1700 that includes the solar cell of FIG. 11B in which a solar cell is formed between the cathode electrode 104 and the anode electrode 106 by the N+ region 204 on the substrate 102 and on and partially or completely around the cathode electrode 104; the P+ region on the substrate and on and partially or completely around the anode electrode 106; the P region 108 on the substrate 102 and on and partially or completely around the P+ region 206; and the N region 112 on the substrate 102 and on and partially or completely around the N+ region 204 and on and partially or completely around the P region 108. Current source 302 in FIG. 16 represents this solar cell. Unlike FIG. 11B, however, FIG. 17 includes the by-pass diode 1608 of FIG. 16. As shown in FIG. 17, substrate 102 can include electrodes 1610 and 1612 on the surface 116 of the substrate 102. An N+ region 204′ can be on the substrate 102 and on and partially or completely around the electrode 1612, and an N region 112′ can be on and partially or completely around the N+ region 204′ and the electrode 1610 as also shown in FIG. 17. A diode 1608 of FIG. 16 can thus be formed as a Schottky diode at the interface between electrode 1610 and N region 112′. The Schottky diode is forward biased for current to flow in the direction of the electrode 1612 to the electrode 1610. Although not visible in FIG. 17, electrode 1610 (the output of the diode 1608) can be connected to the anode electrode 106, and the electrode 1612 (the input of the diode 1608) can be connected to the cathode electrode 104 on substrate 102.

The electrodes 1610 and 1612, like the cathode electrode 104 and the anode electrode 106, can be provided on substrate 102 or can be formed on substrate 102 as discussed above with respect to FIGS. 6 and 7. The electrodes 1610 and 1612 can be directly on the surface 116 of the substrate as shown in FIG. 17, or like the electrodes 104 and 106 as discussed above, can be spaced away from the surface 116. For example, the electrodes 1610 and 1612 can be made of the same material and in the same way as the cathode electrodes 104 and the anode electrodes 106 as discussed above with respect to FIGS. 6 and 7. In some embodiments, the electrodes 1610 and 1612 can comprise aluminum, gold, molybdenum, palladium silicide, platinum silicide, or titanium silicide. In other embodiments, the electrodes 1610 and 1612 can comprise other materials. The N+ region 204′ can be generally similar to the N+ region 204 and can comprise the same materials and can be made in the same way as N+ region 204 as generally discussed above with respect to FIGS. 9A and 9B. For example, the N+ region 204 can be formed on electrode 1612 at the same time or approximately the same time and in the same way as N+ region 204 is formed on the cathode electrodes 104 in FIGS. 9A and 9B. The N region 112′ in FIG. 17 can be generally similar to the N region 112 and can comprise the same materials and be made in the same way as the N region 112 as generally discussed above with respect to FIGS. 11A and 11B. For example, N region 112 can be formed on substrate 102 at the same time or approximately the same time and in the same way as N region 112 is formed in FIGS. 11A and 11B.

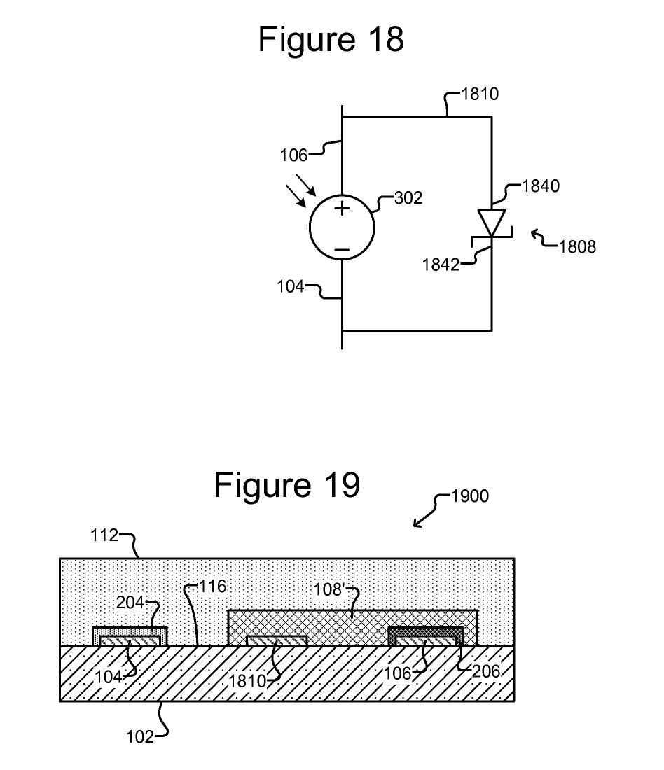

FIG. 18 illustrates a schematic diagram in which a clamping diode 1808 (e.g., a Schottky diode) is connected in parallel with a current source 302, which as discussed above, represents a solar cell formed between a cathode electrode 104 and an anode electrode 106 on the substrate 102. (For example, a first terminal 1840 of the diode 1808 can be connected through an electrode 1810 to the anode electrode 106, and a second terminal 1842 of the diode 1808 can be connected to the cathode electrode 104.) The diode 1808 can prevent the output of the current source 302 from exceeding a predetermined voltage and can thus “clamp” the output voltage of the current source 302 to a voltage equal to or lower than the predetermined voltage. The predetermined voltage corresponds to the forward bias voltage of the diode 1808. The forward bias voltage of the diode 1808 depends on the materials used to make the diode 1808. In some embodiments, the electrode 1810 can comprise aluminum, gold, molybdenum, palladium silicide, platinum silicide, or titanium silicide. In other embodiments, the electrode 1810 can comprise other materials.

The diode 1808 can be made during the same process as the solar cell is made. FIG. 19 illustrates an example according to some embodiments of the invention. Initially, it is noted that FIG. 19 illustrates a solar panel 1900 that includes one of the solar cells of FIG. 11B in which a solar cell is formed between a cathode electrode 104 and an anode electrode 106 by the N+ region 204 on the substrate 102 and on and partially or completely around the cathode electrode 104; the P+ region 206 on the substrate and on and partially or completely around the anode electrode 106; a P region 108′ on the substrate 102 and on and partially or completely around the P+ region 206; and the N region 112 on the substrate 102 and on and partially or completely around the N+ region 204 and on and partially or completely around the P region 108′. Current source 302 in FIG. 18 represents this solar cell. Unlike FIG. 11B, however, FIG. 19 includes the clamping diode 1808 of FIG. 18. As shown in FIG. 19, substrate 102 can include an electrode 1810 on the surface 116 of the substrate 102. As shown, the P region 108′ can be on and partially or completely around not only the P+ region 206 but can also be on and partially or completely around the electrode 1810. A Schottky diode can thus be formed in which a forward bias exists between the electrode 1810 and the cathode electrode 104. Although not visible in FIG. 19, electrode 1810 (the input of the diode 1808) can be connected to the anode electrode 106 on substrate 102.

The electrode 1810, like the cathode electrode 104 and the anode electrode 106, can be provided on substrate 102 or can be formed on substrate 102 as discussed above with respect to FIGS. 6 and 7. For example, the electrode 1810 can be made of the same material and in the same as the cathode electrodes 104 and the anode electrodes 106 as discussed above with respect to FIGS. 6 and 7. Likewise, the P region 108′ can be generally similar to the P region 108 and can comprise the same materials and be made in the same way as P region 108 as generally discussed above with respect to FIGS. 10A and 10B. For example, the P region 108′ can be formed in place of the P region 108 in FIGS. 10A and 10B. The electrode 1810 can be directly on the surface 116 of the substrate 102 as shown in FIG. 19, or like the electrodes 104 and 106 as discussed above, can be spaced away from the surface 116.

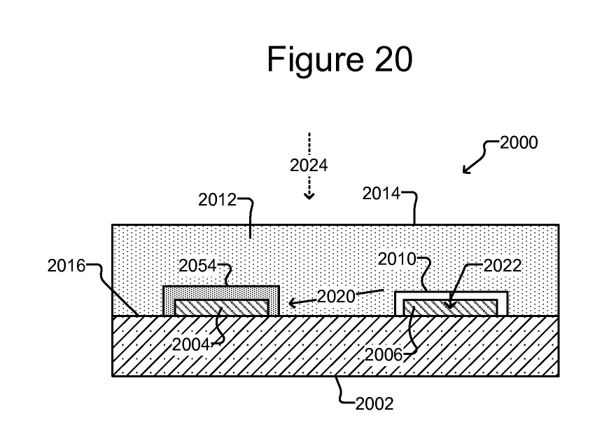

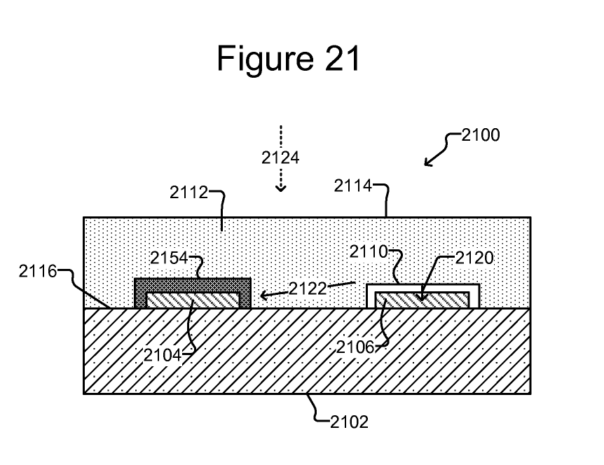

Although the solar cells discussed above are P-N type solar cells, other types of solar cells can be made using the principles discussed herein (e.g., the process illustrated in FIGS. 6-11B). FIGS. 20 and 21 illustrate non-limiting examples of other types of solar cells in the form of Schottky solar cells.

FIG. 20 illustrates a non-limiting example of an N-type Schottky solar cell 2000. As shown in FIG. 20, the solar cell 2000 of FIG. 20 includes a substrate 2002 with a cathode electrode 2004 and an anode electrode 2006 on a surface 2016 of the substrate 2002. The substrate 2002 can be like the substrate 102, the cathode electrode 2004 can be like the cathode electrode 104, and the anode electrode 2006 can be like the anode electrode 106. Cathode electrode 2004 and anode electrode 2006 can be made of the same material and in the same way as cathode electrode 104 and anode electrode 106 as discussed above with respect to FIGS. 6 and 7. An N+ region 2054 can be disposed on the surface 2016 of the substrate 2002 and on and partially or completely around the cathode electrode 2004, and an N region 2012 can be disposed on the surface 2016 of the substrate 2002 and on and partially or completely around the N+ region 2054 and the anode electrode 2006. The N+ region 2054 can comprise the same materials and can be made in the same way as the N+ region 204. For example, N+ region 2054 can be formed on the surface 2016 of the substrate 2002 and on and partially or completely around the cathode electrode 2004 in the same way as N+ region 204 is formed on the cathode electrode 104 as illustrated in FIGS. 9A and 9B and described above with respect to those figures. Similarly, the N region 2012 can comprise the same materials and can be made in the same way as the N region 112. For example, N region 2012 can be formed on the surface 2016 of the substrate 2002 and on and partially or completely around the N+ region 2054 and on and partially or completely around the anode electrode 2006 in the same way as N region 112 is formed on the surface 116 of the substrate 102 and on and partially or completely around the N+ region 204 and on and partially or completely around the P region 108 as illustrated in FIGS. 11A and 11B and described above with respect to those figures. The electrodes 2004 and 2006 can be directly on the surface 2016 of the substrate 2002 as shown in FIG. 20, or like the electrodes 104 and 106 as discussed above, can be spaced away from the surface 2016.

As mentioned, the solar cell illustrated in FIG. 20 is a Schottky solar cell. A Schottky solar cell forms a barrier region 2010 at the interface between the anode electrode 2006 and the N region 2012. Light 124 (e.g., sun light) striking a face 2014 of the solar cell can generate free electron and hole pairs and produce a flow of electrons 2020 from the barrier region 2010 to the cathode electrode 2004 and a corresponding flow of holes 2022 from the barrier region 2010 to the anode electrode 2006. Thus, light 124 striking face 2014 can generate an electrical current through the cathode electrode 2004 and the anode electrode 2006.

FIG. 21 illustrates another non-limiting example of a Schottky solar cell 2100. In FIG. 21, the Schottky solar cell 2100 is a P-type Schottky solar cell. As shown in FIG. 21, the solar cell of FIG. 21 includes a substrate 2102 with a anode electrode 2104 and an cathode electrode 2106 on a surface 2116 of the substrate. The substrate 2102 can be like the substrate 102, the anode electrode 2104 can be like the anode electrode 106, and the cathode electrode 2106 can be like the cathode electrode 104. The anode electrode 2104 and cathode electrode 2006 can be made of the same material and in the same way as cathode electrode 104 and anode electrode 106 as discussed above with respect to FIGS. 6 and 7. A P+ region 2154 can be disposed on the surface 2116 of the substrate 2102 and on and partially or completely around the anode electrode 2104, and a P region 2112 can be disposed on the surface 2116 of the substrate 2102 and on and partially or completely around the P+ region 2154 and the cathode electrode 2106. The P+ region 2154 can comprise the same materials and can be made in the same way as the P+ region 206. For example, the P+ region 2154 can be formed on the surface 2116 of the substrate 2102 and on and partially or completely around the anode electrode 2004 in the same way as P+ region 206 is formed on the cathode electrode 104 as illustrated in FIGS. 9A and 9B and described above with respect to those figures. The P region 2112 can comprise the same materials as the P region 108 and can be made in the same way as the N region 112. For example, the P region 2112 can be formed on the surface 2116 of the substrate 2102 and on and partially or completely around the P+ region 2154 and on and partially or completely around the cathode electrode 2106 in the same way as N region 112 is formed on the surface 116 of the substrate 102 and on and partially or completely around the P+ region 204 and on and partially or completely around the anode electrode 106 as illustrated in FIGS. 11A and 11B and described above with respect to those figures. As mentioned, however, the P region 2112 can comprise the same materials as the P region 108 in FIGS. 10A and 10A. The electrodes 2104 and 2106 can be directly on the surface 2116 of the substrate 2102 as shown in FIG. 21, or like the electrodes 104 and 106 as discussed above, can be spaced away from the surface 2116.

As mentioned, the solar cell 2100 illustrated in FIG. 21 is a Schottky solar cell. A Schottky solar cell forms a barrier region 2110 at the junction between the cathode electrode 2106 and the P region 2112. Light 124 (e.g., sun light) striking a face 2114 of the solar cell 2100 can generate free electron and hole pairs and produce a flow of holes 2122 from the barrier region 2110 to the anode electrode 2104 and a corresponding flow of electrons 2120 from the barrier region 2110 to the cathode electrode 2106. Thus, light 124 striking face 2114 can generate an electrical current through the anode electrode 2104 and the cathode electrode 2106.

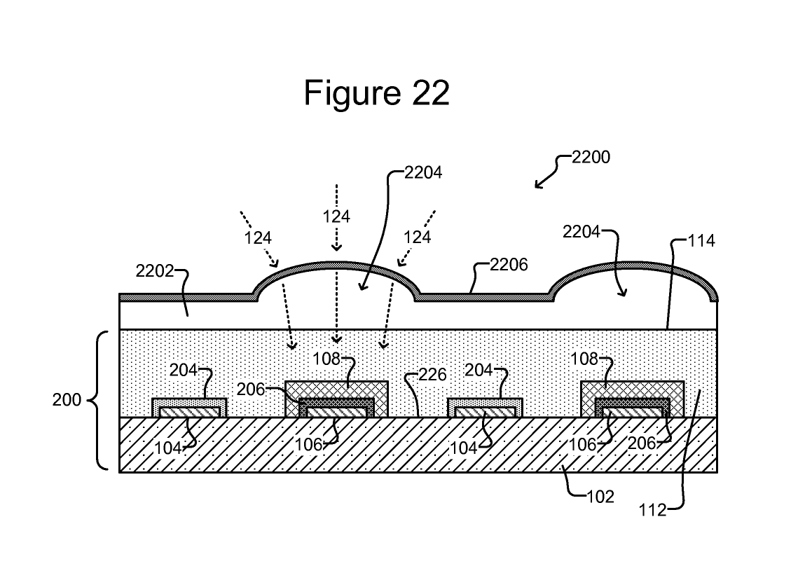

Additional features or elements can optionally be included with any of the embodiments disclosed herein. FIG. 22 illustrates a solar panel 2202 that includes non-limiting example of such additional elements according to some embodiments.

FIG. 22 illustrates the solar panel 200 of FIGS. 11A and 11B with an optical layer 2202 that includes concentrator lenses 2204 and an optical coating 2206. Concentrator lenses 2204 can be configured to magnify light 124 (e.g., sun light) striking the solar panel 2202 and/or focus the light 124 onto the junction between the P region 108 and the N region 112. Although not shown in FIG. 22, as discussed above and illustrated in FIG. 2, a depletion region 110 forms at the interface between the P region 108 and the N region 112. By focusing light onto the junction, the concentrator lenses 2204 focus light onto the depletion region at the junction.

The concentrator lenses 2204 can be part of one or more optical layers 2202 formed on the face 114. The optical layer(s) 2202 can comprise one or more materials that have desired optical characteristics. For example, the materials can be transparent. The optical layer(s) 2202 can be deposited as droplets, for example, through pattern forming print head 804 in the printing apparatus of FIG. 8A. Alternatively, the droplets can be deposited by other means, such as a spray nozzle, or a dropper or in a form other than droplets by a paint brush or other application tool. The droplets can be embossed to form a lens. The deposited droplets can be cured, for example, by heating. In some examples, the droplets can comprise a polymer. Non-limiting examples of suitable materials for optical layer(s) 2202 include monomers and resins. As another example, preformed polymers or glass concentrator lenses 2204 can be applied to the face 114, for example, using an adhesive.

Regardless of the composition of the material or materials that comprise the optical layer(s) 2202, the material(s) that forms layer(s) 2202 can be disposed in patterns to form concentrator lenses 2204 to magnify and/or focus the light 124 onto the junction between the P region 108 and the N region 112 as discussed above. For example, layer(s) 2202 can be deposited to form concentrator lenses 2204 in the shape of optical lenses shaped as appropriate to magnify or focus the light 124 as discussed above. It should be noted that the optical layer(s) 2202 can alternatively or additionally seal and/or protect the underlying regions (e.g., the P region 112) from moisture and wear. As another possibility, optical layer(s) 2202 can alternatively or additionally comprise a material that is abrasive resistant and thus resists scratching or similar physical damage.

As also shown in FIG. 22, an optical coating 2206 comprising one or more layers of a material configured to provide optical enhancements can be deposited onto the optical layer(s) 2202. In some examples, the optical coating 2206 can be an anti-reflective material that reduces the amount of the light 124 that reflects away from the solar panel 2202 or, put another way, increases the amount of the light 124 that enters the solar panel 2202. The optical coating 2206 can comprise one or more materials that have desired optical characteristics. For example, as mentioned above, the material(s) can have non-reflective properties. The optical coating 2206 can be deposited as droplets, for example, through print head 804 in the printing apparatus of FIG. 8. Alternatively, the droplets can be deposited by other means, such as a spray nozzle, or a dropper or in a form other than droplets by a paint brush or other application tool, including without limitation physical vapor deposition (PVD) and chemical vapor deposition (CVD). The deposited droplets can be cured, for example, by heating. Non-limiting examples of suitable materials for optical layer(s) 2202 include polymers and organic materials. For example, silicon nitride can be used for optical layer(s) 2202. Optical layers can include, for example, ¼ wavelength thickness layers and materials with tuned refractive index to provide an anti-reflective coating.

In some embodiments, the optical layer(s) 2202 need not be included and the optical coating 2260 can be applied directly to the face 114. In other embodiments, the optical layer(s) 2202 can be utilized without the optical coating 2206. Although the optical layer(s) 2202 and the optical coating 2206 are illustrated in FIG. 22 as used with the solar panel 200 of FIGS. 11A and 11B, the optical layer(s) 2202 and/or the optical coating 2206 can be used with any of the embodiments illustrated in FIGS. 1, 12, 13, 14A, 15, 17, 19, 20, and 21.

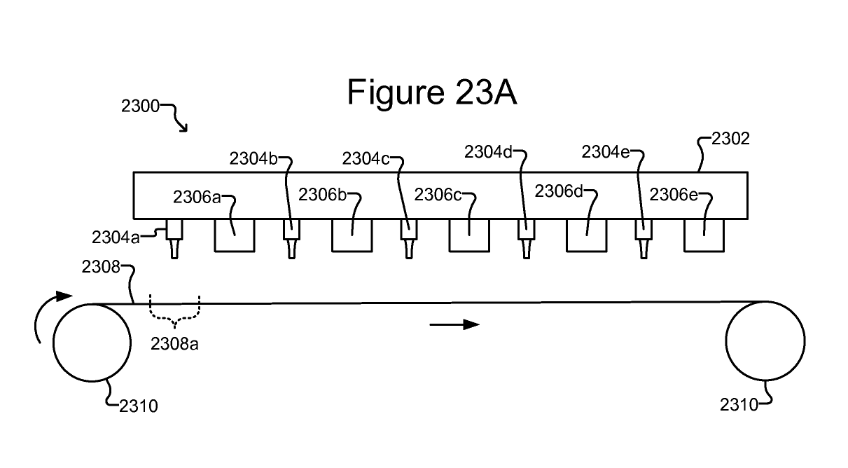

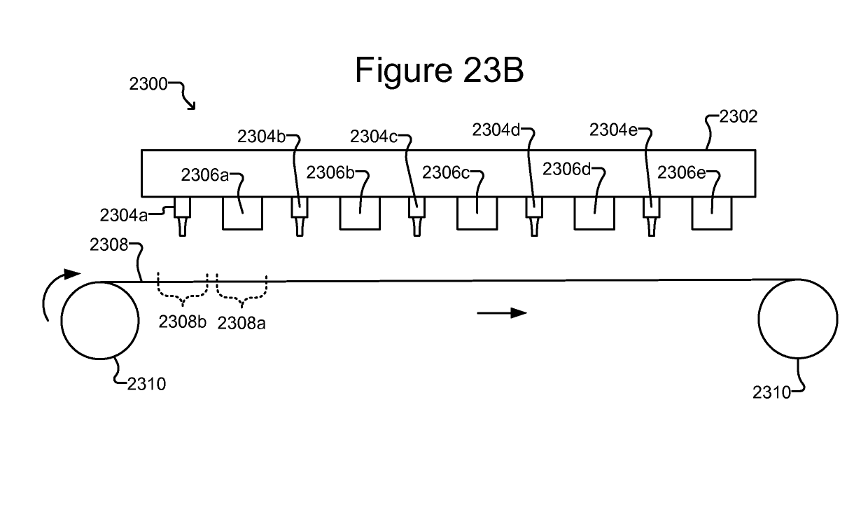

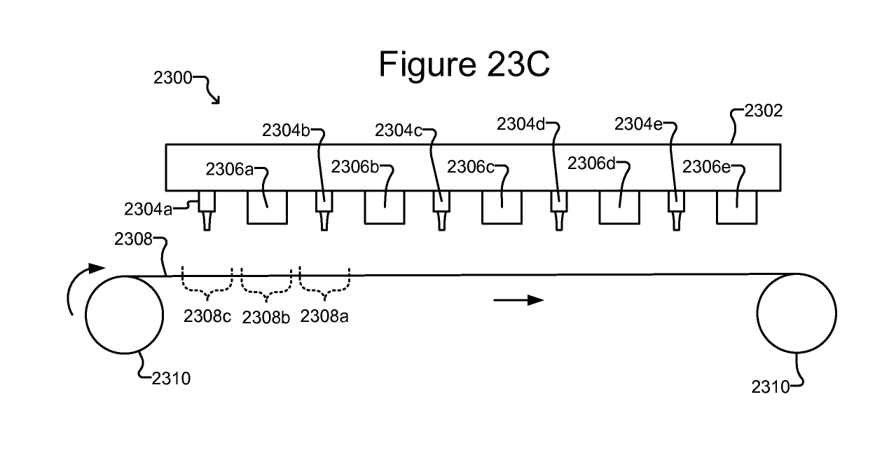

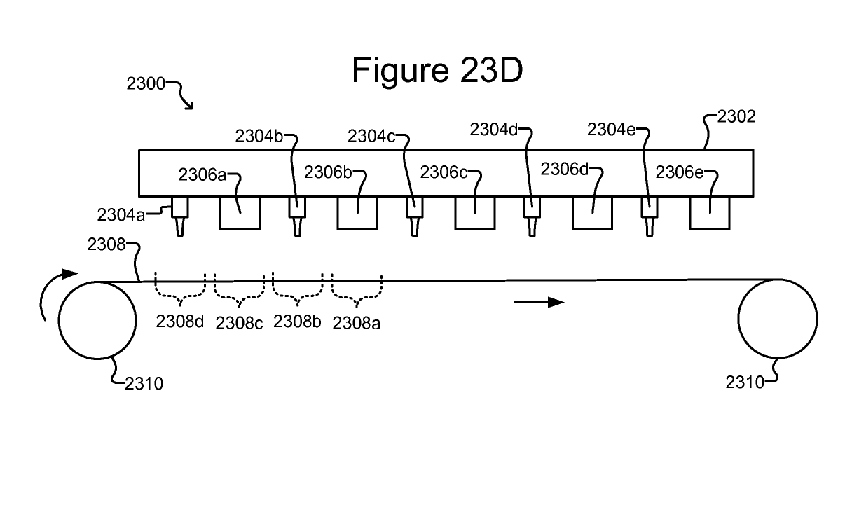

FIGS. 23A-23D illustrates an example of a system 2300 that can be used to make solar panels like the solar panels disclosed herein according to some embodiments. As shown, system 2300 can include a controller 2302, delivery nozzles 2304a-e, driers 2306a-e, and rollers 2310. A solar cell film 2308 (e.g., a polymer based flexible sheet of material) can be initially rolled around one of the rollers 2310 and can then be unrolled from that roller 2310 to the other roller 2310 as shown in FIGS. 23A-23D. As also shown, the solar cell film 2308 can be rolled past the delivery nozzles 2304a-e and driers 2306a-e. Although five delivery nozzles 2304a-e and five driers 2306a-e are shown in the non-limiting example of FIGS. 23A-23D, more or fewer delivery nozzles and/or driers can be included. The delivery nozzles 2304a-e can be a print head configured to print droplets of material. For example delivery nozzles 2304a-e can be an ink jet print head. Delivery nozzles 2304a-e can be moveable with respect to the solar cell film 2308.

A solar panel (e.g., like any of solar panels 100, 200, 1200, 1300, 1400, 1500,1700, 1900, 2000, 2100, or 2200) can be formed on portions (e.g., portions 2308a-d) of the solar cell film 2308. Although four portions 2308a-d of the solar cell film 2308 are illustrated in FIGS. 23A-23D corresponding to four solar panels to be made on each of the four portions 2308a-d, fewer or more than four solar panels can be made on many more than four portions of the solar cell film 2308. Each portion 2308a-d of the solar cell film 2308 can be sequentially positioned under the delivery nozzles 2304a-e and the driers 2306a-e. While a particular portion (e.g., 2308a) of the solar cell film 2308 is positioned under each delivery nozzle 2304a-e, material forming particular elements of a solar panel can be deposited from the delivery nozzle onto the particular portion (e.g., 2308a) of the solar cell film 2308. The driers 2306a-e can dry the materials deposited by the delivery nozzles 2304a-e.

Although the system illustrated in FIGS. 23A-23D can be used to make any of the solar panels (e.g., 100, 200, 1200, 1300, 1400, 1500, 1700, 1900, 2000, or 2100) illustrated herein, for illustration and ease of discussion and not by way of limitation, an example is discussed below in which the system 2300 of FIGS. 23A-23D is utilized to make the solar panel 200 of FIGS. 11A and 11B on portions 2308a, 2308b, 2308c, and 2308d of the solar cell film 2308.

As shown in FIG. 23A, a first portion 2308a of the solar cell film 2308 can initially be positioned under the first delivery nozzle 2304a. A first material can then be deposited (e.g., droplets of the material can be printed through the first delivery nozzle 2304a) onto the first portion 2308a of the solar cell film 2308 to form the cathode electrodes 104, anode electrodes 106, connectors 402 and 404, and terminals 406 and 408 as shown in FIG. 6 except, of course, that the cathode electrodes 104, anode electrodes 106, connectors 402 and 404, and terminals 406 and 408 are formed on the first portion 2308a of the solar cell film 2308 rather than the substrate 102 shown in FIG. 6. The first material deposited through the first nozzle 2304a can be the same material discussed above with respect to FIG. 6 that forms the cathode electrodes 104, anode electrodes 106, connectors 402 and 404, and terminals 406 and 408.

Next, as shown in FIG. 23B, the solar cell film 2308 can moved such that the first portion 2308a is under the first drier 2306a and a second portion 2308b of the solar cell film 2308 is under the first delivery nozzle 2304a. The first drier 2306a can then dry the first material deposited on the first portion 2308a of the solar cell film 2308, and the first material can be deposited through the first delivery nozzle 2304a onto the second portion 2304b of the solar cell film 2304 to form the cathode electrodes 104, anode electrodes 106, connectors 402 and 404, and terminals 406 and 408 as generally shown in FIG. 6 on the second portion 2308b of the solar cell film 2308.

As shown in FIG. 23C, the solar cell film 2308 can be moved again such that the first portion 2308a is under the second delivery nozzle 2304b, the second portion 2308b is under the first drier 2306a, and a third portion 2308c of the solar cell film 2308 is under the first delivery nozzle 2304a. A second material can then be deposited (e.g., droplets of the material can be printed through the second delivery nozzle 2304b) onto the first portion 2304a of the solar cell film 2304 to form N+ regions 204 generally as shown in FIGS. 9A and 9B on the first portion 2308a of the solar cell film 2308. In addition, the first drier 2306a can dry the first material deposited on the second portion 2308b of the solar cell film 2308, and the first material can be deposited onto the third portion 2308c of the solar cell film 2308 to form the cathode electrodes 104, anode electrodes 106, connectors 402 and 404, and terminals 406 and 408 as generally shown in FIG. 6. The second material deposited through the second nozzle 2304b can be the same material discussed above with respect to FIGS. 9A and 9B that forms the N+ region 204.

As shown in FIG. 23D, the solar cell film 2308 can again be moved such that the first portion 2308a is under the second drier 2306b, the second portion 2308b is under the second delivery nozzle 2304b, the third portion 2308c is under the first drier 2306a, and a fourth portion 2308d is under the first delivery nozzle 2304a. The second drier 2306b can dry the second material deposited onto the first portion 2308a. In addition, the second material can be deposited (e.g., droplets of the material can be printed through the second delivery nozzle 2304b) onto the second portion 2304b of the solar cell film 2304 to form N+ regions 204 generally as shown in FIGS. 9A and 9B. In addition, the first drier 2306a can dry the first material deposited on the third portion 2308c of the solar cell film 2308, and the first material can be deposited onto the fourth portion 2308d of the solar cell film 2308 to form the cathode electrodes 104, anode electrodes 106, connectors 402 and 404, and terminals 406 and 408 as generally shown in FIG. 6.

The foregoing process of advancing the solar cell film 2308 can continue, and the first portion 2308a of the solar cell film 2308 can be positioned under the third delivery nozzle 2304c, then the third drier 2306c, then the fourth delivery nozzle 2304d, then the fourth drier 2306d, then the fifth delivery nozzle 2304e, and then the fifth drier 2306e. While under the third delivery nozzle 2304c, a third material can be deposited (e.g., droplets of the material can be printed through the third delivery nozzle 2304c) onto the first portion 2308a of the solar cell film 2308 to form P+ regions 206 generally as shown in FIGS. 9A and 9B on the first portion 2308a of the solar cell film 2308. The third material deposited through the third nozzle 2304c can be the same material discussed above with respect to FIGS. 9A and 9B that forms the P+ region 206. While the first portion 2308a of the solar cell film 208 is under the third drier 2306c, the third drier can dry the third material deposited on the first portion 2308a. While under the fourth delivery nozzle 2304d, a fourth material can be deposited (e.g., droplets of the material can be printed through the fourth delivery nozzle 2304c) onto the first portion 2304a of the solar cell film 2304 to form P regions 108 generally as shown in FIGS. 10A and 10B on the first portion 2308a of the solar cell film 2308. The fourth material deposited through the fourth nozzle 2304d can be the same material discussed above with respect to FIGS. 10A and 10B that forms the P region 108. While the first portion 2308a of the solar cell film 2308 is under the fourth drier 2306d, the fourth drier can dry the fourth material deposited on the first portion 2308a. While under the fifth delivery nozzle 2304e, a fifth material can be deposited (e.g., droplets of the material can be printed through the fifth delivery nozzle 2304e) onto the first portion 2304a of the solar cell film 2304 to form N region 112 generally as shown in FIGS. 11A and 11B on the first portion 2308a of the solar cell film 2308. The fifth material deposited through the fifth nozzle 2304e can be the same material discussed above with respect to FIGS. 11A and 11B that forms the N region 112. While the first portion 2308a of the solar cell film 2308 is under the fifth drier 2306e, the fifth drier can dry the fifth material deposited on the first portion 2308a.

The solar panel 200 of FIGS. 11A and 11B can thus be made on portion 2308a of the solar cell film 2308 using the system of FIGS. 23A-23D. The portion 2308a can then be removed (e.g., cut out of) the solar cell film 2308 before the solar cell film 2308 is taken up by the roller 2310. As should be apparent, similar solar panels can be made on subsequent portions (e.g., 2308b-d) of the solar cell film 2308 in the same manner. As mentioned, solar panels other than solar panel 200 (e.g., 100, 1200, 1300, 1400, 1500, 1700, 1900, 2000, and 2100) can be made using a system like the system 2300.

1. A solar panel comprising:
a substrate having a surface; and
layers of droplets of different materials disposed on the surface of the substrate, wherein the layers of materials comprise:
an outer layer disposed away from the surface of the substrate, the outer layer comprising a face of the solar panel;
a cathode electrode disposed between the outer layer and the surface of the substrate;
an anode electrode disposed between the outer layer and the surface of the substrate;
a P region disposed at least partially around the anode electrode and the P region comprising droplets of a P material comprising P-doped semiconductor particles, and
an N region disposed at least partially around the P region and at least partially around the cathode electrode, the N region comprising droplets of an N material comprising N-doped semiconductor particles.

2. The solar panel of claim 1, wherein the cathode electrode and the anode electrode are disposed directly on the surface of the substrate.

3. The solar panel of claim 1, wherein the layers of materials further comprises:
an N+ region disposed at least partially around the cathode electrode between the cathode electrode and the N region, the N+ region comprising droplets of a material comprising semiconductor particles with a greater concentration of N-doping than the N material; and
a P+ region disposed at least partially around the anode electrode between the anode electrode and the P region, the P+ region comprising droplets of a material comprising semiconductor particles with a greater concentration of P-doping than the P material.

4. The solar panel of claim 1, wherein:
the layers further comprise a first upper region disposed above the P region and a first neck region disposed between and interconnecting the P region and the first upper region, the first neck region being more narrow than the P region and the first upper region, and
the first neck region and the first upper region comprise droplets of the P material comprising the P-doped semiconductor particles.

5. The solar panel of claim 4, wherein:
the layers further comprise a second upper region and a second neck region disposed between and interconnecting the first upper region and the second upper region, the second neck region being more narrow than the first upper region and the second upper region, and
the second neck region and the second upper region comprise droplets of the P material comprising the P-doped semiconductor particles.

6. The solar panel of claim 1 further comprising a concentrator lens for focusing light disposed on the outer layer.

7. The solar panel of claim 1 further including a by-pass diode, a first terminal of the diode electrically connected to the cathode electrode and a second terminal of the diode electrically connected to the anode electrode, the diode being forward biased from the cathode electrode to the anode electrode, wherein the diode is formed in the layers of droplets disposed on the surface of the substrate.

8. The solar panel of claim 1 further including a clamping diode electrically connected to the cathode electrode and the anode electrode and forward biased from the anode electrode to the cathode electrode, wherein the diode is formed in the layers of droplets disposed on the surface of the substrate.

9. A method of making a solar panel, the method comprising:
depositing a plurality of layers of droplets of different materials on a surface of a substrate and on a cathode electrode and an anode electrode located on the surface of the substrate,
wherein the depositing a plurality of layers of droplets of different materials comprises:
forming a P region at least partially around the anode electrode by depositing a plurality of droplets of a P material comprising P-doped semiconductor particles onto the surface of the substrate and at least partially around the anode electrode; and
forming an N region at least partially around the cathode electrode by depositing a plurality of droplets of an N material comprising N-doped semiconductor particles onto the surface and at least partially around the cathode electrode and the P region.

10. The method of claim 9, wherein:
the forming the P region comprises:
depositing the droplets of the P material in liquid form through a spray head, and
hardening the deposited droplets of the P material; and
the forming the N region comprises:
depositing the droplets of the N material in liquid form through a spray head, and
hardening the deposited droplets of the N material.

11. The method of claim 10, wherein:
the P-doped semiconductor particles comprise nano-particles of silicon doped with a P dopant in a concentration of 1×10¹⁴ to 1×10¹⁶ atoms per cubic centimeter;
the hardening the deposited droplets of the P material comprises heating the deposited droplets of the P material to a temperature of 150 to 250 degrees Celsius;
the N-doped semiconductor particles comprise nano-particles of silicon doped with an N dopant in a concentration of 1×10¹⁴ to 1×10¹⁶ atoms per cubic centimeter; and
the hardening the deposited droplets of the N material comprises heating the deposited droplets of the N material to a temperature of 150 to 250 degrees Celsius.

12. The method of claim 11, wherein the depositing the plurality of layers of droplets of the different materials further comprises:
forming a P+ region at least partially around the anode electrode between the anode electrode and the P region by depositing a plurality of droplets of a P+ material comprising P+ semiconductor particles with a greater concentration of P-doping than the P material, and forming an N+ region at least partially around the cathode electrode between the cathode electrode and the N region by depositing a plurality of droplets of an N+ material comprising N+ semiconductor particles with a greater concentration of N-doping than the N material.

13. The method of claim 12, wherein:
the forming the P+ region comprises:
depositing the plurality of droplets of the P+ material in liquid form through a spray head, and
hardening the deposited droplets of the P+ material; and
the forming the N+ region comprises:
depositing the plurality of droplets of the N+ material in liquid form through a spray head, and
hardening the deposited droplets of the N+ material.

14. The method of claim 13, wherein:
the P+ semiconductor particles comprise nano-particles of silicon doped with a P dopant in a concentration greater than 1×10²⁰ atoms per cubic centimeter;
the hardening the deposited droplets of the P+ material comprises heating the deposited droplets of the P+ material to a temperature of 150 to 250 degrees Celsius;
the N+ doped semiconductor particles comprise nano-particles of silicon doped with an N dopant in a concentration greater than 1×10²⁰ atoms per cubic centimeter; and
the hardening the deposited droplets of the N+ material comprises heating the deposited droplets of the N+ material to a temperature of 150 to 250 degrees Celsius.

15. The method of claim 9, wherein the depositing the plurality of layers of droplets of different materials further comprises forming a concentrator lens on the N region for focusing incident light onto a junction of the P region and the N region by depositing a plurality of droplets of an optical material on the N region.

16. The method of claim 9, wherein the cathode electrode and the anode electrode are located directly on the surface of the substrate.

17. A method of generating an electric current, the method comprising:
exposing a face of a solar panel to light, the face comprising an outer layer of a plurality of layers of droplets of different materials disposed on a surface of a substrate,
wherein:
the light enters the layers and strikes a depletion region between a P region and an N region within the layers,
the P region is disposed at least partially around an anode electrode located on the surface of the substrate, and the P region comprises droplets of a material comprising P-doped semiconductor particles,
the N region is disposed at least partially around the P region and at least partially around a cathode electrode located on the surface of the substrate, and the N region comprises droplets of a material comprising N-doped semiconductor particles, and
the light striking the depletion region generates a current flow from the cathode electrode to the anode electrode.

18. The method of claim 17, wherein the cathode electrode and the anode electrode are located directly on the surface of the substrate.

19. The method of claim 18, wherein the face comprises a concentrator lens disposed on the N region, wherein the method further comprises the concentrator lens focusing the light onto the depletion region.

20. The method of claim 18, wherein the face comprises a concentrator lens disposed on the N region, wherein the method further comprises the concentrator lens magnifying the light entering the layers.

21. A solar panel comprising:
a substrate comprising a cathode electrode disposed on a first base, the first base having a triangular cross-section with converging sidewalls each disposed at an angle with respect to the surface of the substrate of 20 to 70 degrees, the substrate further comprising an anode electrode disposed on a second base, the second base having a triangular cross-section with converging sidewalls each disposed at an angle with respect to the surface of the substrate of 20 to 70 degrees; and
layers of droplets of materials disposed on the surface of the substrate, the cathode, and the anode, wherein the layers of materials comprise:
an outer layer disposed away from the surface of the substrate, the outer layer comprising angled portions each angled with respect to the surface of the substrate at an angle that is approximately equal to one of the angles of one of the sidewalls of the first base or the second base;
a P region disposed at least partially around the anode electrode, the P region comprising droplets of a P material comprising P-doped semiconductor particles, and
an N region disposed at least partially around the P region and at least partially around the cathode electrode, the N region comprising droplets of an N material comprising N-doped semiconductor particles.

22. The solar panel of claim 21, wherein the N region comprises the outer layer.

23. The solar panel of claim 21, wherein the layers of materials further comprises:
an N+ region disposed at least partially around the cathode electrode between the cathode electrode and the N region, the N+ region comprising droplets of a material comprising semiconductor particles with a greater concentration of N-doping than the N material; and
a P+ region disposed at least partially around the anode electrode between the anode electrode and the P region, the P+ region comprising droplets of a material comprising semiconductor particles with a greater concentration of P-doping than the P material.

24. The solar panel of claim 23, wherein:
the P+ region is angled with respect to the surface of the substrate at angles that are approximately equal to the angles of the sidewalls of the second base, and
the N+ region is angled with respect to the surface of the substrate at angles that are approximately equal to the angles of the sidewalls of the first base.

25. The solar panel of claim 24, wherein:
the layers further comprise an upper region disposed above the P region and comprising a first angled portion and a second angled portion each angled with respect to the surface of the substrate at angles that are approximately equal to the angles of the sidewalls of the second base,
the layers further comprise a neck region disposed between and interconnecting the P region and the upper region, the neck region being more narrow than the P region and the upper region, and
the neck region and the upper region comprise droplets of the P material comprising the P-doped semiconductor particles.

26-50. (canceled)
